(19) United States
(12) Patent Application Publication
(10) Pub. No.: US 2024/0310718 A1
(43) Pub. Date: Sep. 19, 2024

(54) METHOD FOR GENERATING MASK PATTERN

(71) Applicant: ASML NETHERLANDS B.V., Veldhoven (NL)

(72) Inventors: Ayman HAMOUDA, Milpitas, CA (US); Dong MAO, San Jose, CA (US)

(73) Assignee: ASML NETHERLANDS B.V., Veldhoven (NL)

(21) Appl. No.: 18/578,299

(22) PCT Filed: Jul. 4, 2022
(86) PCT No.: PCT/EP2022/068437

§ 371 Date: Jan. 10, 2024

Related U.S. Application Data
(60) Provisional application No. 63/227,603, filed on Jul. 30, 2021.

(51) Int. Cl. G03F 1/36; G03F 1/70

(52) U.S. Cl. CPC G03F 1/36; G03F 1/70

(57) ABSTRACT

A method for generating a mask pattern for a lithographic process. The method involves generating a smoothed representation of a segmented mask pattern by applying a first smoothing function and adjusting the segmented mask pattern by with a set of changes to one or more of the plurality of segmented features. Further, a patterning process simulation is performed in an iterative manner by using the smoothed mask pattern of an adjusted segmented mask pattern until a termination condition is satisfied. In each iteration, upon adjusting the segmented mask pattern, a smoothed mask pattern is generated and used by process models to simulate the patterning process. Once the termination condition is satisfied, a resultant segmented mask pattern is obtained. Then, a final mask pattern is generated by applying a second smoothing function to a resultant segmented mask pattern.

### CROSS-REFERENCE TO RELATED APPLICATIONS

This application claims priority of U.S. application No. 63/227,603 which was filed on Jul. 30, 2021 and which is incorporated herein in its entirety by reference.

### FIELD

The present disclosure relates to mechanisms of mask pattern generation in connection with a patterning process and lithographic apparatus.

### BACKGROUND

A lithography apparatus is a machine that transfers a desired pattern onto a target portion of a substrate. Lithography apparatus can be used, for example, in the manufacture of integrated circuits (ICs). In that circumstance, a patterning device, which is alternatively referred to as a mask or a reticle, may be used to generate a circuit pattern corresponding to an individual layer of the IC, and this pattern can be imaged onto a target portion (e.g., comprising part of, one or several dies) on a substrate (e.g., a silicon wafer) that has a layer of radiation-sensitive material (resist). In general, a single substrate contains a network of adjacent target portions that are successively exposed. Known lithography apparatus include so-called steppers, in which each target portion is irradiated by exposing an entire pattern onto the target portion in one go, and so-called scanners, in which each target portion is irradiated by scanning the pattern through the beam in a given direction (the “scanning”-direction) while synchronously scanning the substrate parallel or anti parallel to this direction.

Prior to transferring the circuit pattern from the patterning device to the substrate, the substrate may undergo various processes, such as priming, resist coating and a soft bake. After exposure, the substrate may be subjected to other processes, such as a post-exposure bake (PEB), development, a hard bake and measurement/inspection of the transferred circuit pattern. This array of processes is used as a basis to make an individual layer of a device, e.g., an IC device. The substrate may then undergo various processes to produce the individual layer of the device, such as etching, ion-implantation (doping), metallization, oxidation, chemo-mechanical polishing, etc. If several layers are required in the device, then the whole procedure, or a variant thereof, can be repeated for each layer. Eventually, a device will be present in each target portion on the substrate. These devices are then separated from one another by a technique such as dicing or sawing, whence the individual devices can be mounted on a carrier, connected to pins, etc.

Thus, manufacturing semiconductor devices, typically involves processing a substrate (e.g., a semiconductor wafer) using a number of fabrication processes to form various features and multiple layers of the devices. Such layers and features are typically manufactured and processed using, e.g., deposition, lithography, etch, chemical-mechanical polishing, and ion implantation. Multiple devices may be fabricated on a plurality of dies on a substrate and then separated into individual devices. The device manufacturing typically includes a patterning process. A patterning process involves a patterning step, such as optical and/or nanoimprint lithography using a patterning device (e.g., a mask) in a lithographic apparatus, to transfer a pattern on the patterning device to a substrate and typically, but optionally, involves one or more related pattern processing steps, such as resist development by a development apparatus, baking of the substrate using a bake tool, etching using the pattern using an etch apparatus, etc.

### SUMMARY

Semiconductor manufacturing involves generating mask patterns so that nanoscale features of a circuit can be accurately printed on a chip. However, generating mask patterns is a time consuming process and requires fine adjustments of mask features so that desired circuit pattern can be printed on the chip using the mask pattern. The adjusting process involves moving or changing the shape of one or more portions of the mask features to meet a printing performance characteristic related to the circuit to be printed on the chip. Such adjustment of the mask features is not a trivial process, as there may be cross interactions between different mask features. The cross interactions are particularly amplified when feature sizes are small (e.g., less than 10 nm) thereby affecting how accurately the circuit gets printed on the chip.

Some of the existing semiconductor manufacturing processes employ curved mask features for accurate printing of the circuit. The curved mask features may be generated by simulations involving dissecting and adjusting small portions of each mask features and analyzing impact of changing these portions of mask features. The dissecting and analyzing of impact of adjusting small portions of each mask feature is very challenging and computationally intensive to simulate.

According to the present disclosure, mechanisms are provided herein for efficient and flexible multi-variable solver that can be employed in mask optimization to generate mask patterns. In an embodiment, there is provided a method that involves generating a smoothed representation of a segmented mask pattern (e.g., by applying a first smoothing function) and adjusting the segmented mask pattern by with a set of changes to one or more of the plurality of segmented features. A patterning process simulation is performed in an iterative manner by using the smoothed mask pattern of an adjusted segmented mask pattern until a termination condition is satisfied. In each iteration, upon adjusting the segmented mask pattern, a smoothed mask pattern is generated and fed to the one or more process models to simulate the patterning process. Once the termination condition is satisfied, a resultant segmented mask pattern is obtained. Then, a final mask pattern is generated by applying a second smoothing function to a resultant segmented mask pattern.

In an embodiment, the method for generating a mask pattern for a lithographic process involves accessing a first segmented mask pattern comprising a plurality of segmented features of a first mask pattern; generating a smoothed representation of the first segmented mask pattern by applying a first smoothing function; adjusting the first segmented mask pattern by with a set of changes to one or more of the plurality of segmented features; generating, using the first smoothing function, a smoothed representation of the adjusted segmented mask pattern; evaluating the smoothed representation by simulating a patterning process using the smoothed representation of the adjusted segmented mask pattern; obtaining, based on the adjusted segmented mask pattern, a resultant segmented mask pattern; and generating, based on a second smoothing function and the resultant segmented mask pattern, a mask pattern having smoothed features.

In an embodiment, the obtaining of the resultant segmented mask pattern is an iterative process, each iteration comprising simulating the patterning process that includes process models configured to apply the smoothing function to the segmented mask pattern. Each iteration of the obtaining of the resultant segmented mask pattern involves (a) adjusting the first segmented mask pattern with a first change of the set of changes of the more or more of the plurality of segmented features; (b) generating, using the first smoothing function, the smoothed representation of the adjusted segmented mask pattern; (c) globally evaluating the simulation results based on the adjusted segmented pattern; (d) determining whether the simulation results satisfy the termination condition; and (e) responsive to the termination condition not being satisfied, adjusting, based on the evaluation, the first segmented mask pattern with a second change of the set of changes of the one or more of the plurality of segmented features, and repeating steps (b)-(e).

In an embodiment, the evaluating involves evaluating a cost function that measures an impact on a lithographic metric from the set of changes to the plurality of segmented features for a plurality of lithographic process conditions, wherein the cost function comprises a function of the smoothed representation. In an embodiment, a Jacobian matrix may be computed to evaluate a global impact on resist image from a change in a segment. In an embodiment, the Jacobian matrix is a set of derivatives of a function of the smoothed representation with respect to the plurality of segments of the first segmented mask pattern.

Furthermore, in an embodiment, there is provided a non-transitory computer-readable media comprising instructions that, when executed by one or more processors, cause operations including steps of the methods discussed above.

### BRIEF DESCRIPTION OF THE DRAWINGS

Embodiments will now be described, by way of example only, with reference to the accompanying drawings in which:

FIG. 1 schematically depicts a lithography apparatus, according to an embodiment;

FIG. 2A shows a curvilinear mask superimposed with control points and target features for visual reference, according to an embodiment;

FIG. 2B illustrates impact of an adjacent feature on a shape of a first portion of a curved mask feature of the curvilinear mask of FIG. 2A, according to an embodiment of the present disclosure;

FIG. 2C illustrates impact of an adjacent feature on a shape of a second portion of the curved mask feature of the curvilinear mask of FIG. 2A, according to an embodiment of the present disclosure;

FIG. 2D illustrates impact of an adjacent feature on a shape of a third portion of the curved mask feature of the curvilinear mask of FIG. 2A, according to an embodiment of the present disclosure;

FIG. 3A is an exemplary flow chart of a method for determining a mask pattern, according to an embodiment of the present disclosure;

FIG. 3B is an exemplary flow chart of a process for a resultant mask pattern, according to an embodiment of the present disclosure;

FIG. 4 illustrates, using exemplary patterns, generation of a mask pattern using the method of FIG. 3A, according to an embodiment of the present disclosure;

FIG. 5 illustrates an exemplary integration of mask rule check in the process of generating a mask pattern, according to an embodiment of the present disclosure;

FIG. 6 is a flowchart of method steps for model-based OPC, according to an embodiment of the present disclosure;

FIG. 7 is a diagram of a feature and an assumed simulated resist image showing edge placement errors, according to an embodiment of the present disclosure;

FIG. 8 is a diagram of a feature and an assumed simulated resist image showing edge placement errors, according to an embodiment of the present disclosure;

FIG. 9A shows movements of segments of the edges of an exemplary main feature and an exemplary assist feature, according to an embodiment of the present disclosure;

FIG. 9B shows that additional dissecting points may be added to the feature in FIG. 9A.

FIG. 9C illustrates a metric that measures difference between reconfiguration of a feature in one die and a corresponding feature in another die, according to an embodiment of the present disclosure;

FIG. 9D illustrates the necking constraint, according to an embodiment of the present disclosure;

FIG. 9E illustrates the bridging constraint, according to an embodiment of the present disclosure;

FIG. 10 is a block diagram of an exemplary computer system, according to an embodiment;

FIG. 11 is a diagram of an exemplary extreme ultraviolet (EUV) lithographic projection apparatus, according to an embodiment;

FIG. 12 is a more detailed view of the exemplary apparatus in FIG. 11, according to an embodiment; and

FIG. 13 is a more detailed view of the source collector module of the apparatus of FIG. 11 and FIG. 12, according to an embodiment.

### DETAILED DESCRIPTION

Although specific reference may be made in this text to the use of lithography apparatus in the manufacture of ICs, it should be understood that the lithography apparatus described herein may have other applications, such as the manufacture of integrated optical systems, guidance and detection patterns for magnetic domain memories, liquid-crystal displays (LCDs), thin film magnetic heads, etc. The skilled artisan will appreciate that, in the context of such alternative applications, any use of the terms “wafer” or “die” herein may be considered as synonymous with the more general terms “substrate” or “target portion”, respectively. The substrate referred to herein may be processed, before or after exposure, in for example a track (a tool that typically applies a layer of resist to a substrate and develops the exposed resist) or a metrology or inspection tool. Where applicable, the disclosure herein may be applied to such and other substrate processing tools. Further, the substrate may be processed more than once, for example in order to create a multi-layer IC, so that the term substrate used herein may also refer to a substrate that already contains multiple processed layers.

The terms “radiation” and “beam” used herein encompass all types of electromagnetic radiation, including ultraviolet (UV) radiation (e.g. having a wavelength of 365, 248, 193, 157 or 126 nm) and extreme ultra-violet (EUV) radiation (e.g. having a wavelength in the range of 5-20 nm), as well as particle beams, such as ion beams or electron beams.

The term “patterning device” used herein should be broadly interpreted as referring to a device that can be used to impart a radiation beam with a pattern in its cross-section such as to create a pattern in a target portion of the substrate. It should be noted that the pattern imparted to the radiation beam may not exactly correspond to the desired pattern in the target portion of the substrate. Generally, the pattern imparted to the radiation beam will correspond to a particular functional layer in a device being created in the target portion, such as an integrated circuit.

A patterning device may be transmissive or reflective. Examples of patterning device include masks, programmable mirror arrays, and programmable LCD panels. Masks are well known in lithography, and include mask types such as binary, alternating phase-shift, and attenuated phase-shift, as well as various hybrid mask types. An example of a programmable mirror array employs a matrix arrangement of small mirrors, each of which can be individually tilted so as to reflect an incoming radiation beam in different directions; in this manner, the reflected beam is patterned.

The support structure holds the patterning device. It holds the patterning device in a way depending on the orientation of the patterning device, the design of the lithographic apparatus, and other conditions, such as for example whether or not the patterning device is held in a vacuum environment. The support can use mechanical clamping, vacuum, or other clamping techniques, for example electrostatic clamping under vacuum conditions. The support structure may be a frame or a table, for example, which may be fixed or movable as required and which may ensure that the patterning device is at a desired position, for example with respect to the projection system. Any use of the terms “reticle” or “mask” herein may be considered synonymous with the more general term “patterning device”.

The term “projection system” used herein should be broadly interpreted as encompassing various types of projection system, including refractive optical systems, reflective optical systems, and catadioptric optical systems, as appropriate for example for the exposure radiation being used, or for other factors such as the use of an immersion fluid or the use of a vacuum. Any use of the term “projection lens” herein may be considered as synonymous with the more general term “projection system”.

The illumination system may also encompass various types of optical components, including refractive, reflective, and catadioptric optical components for directing, shaping, or controlling the beam of radiation, and such components may also be referred to below, collectively or singularly, as a “lens.”

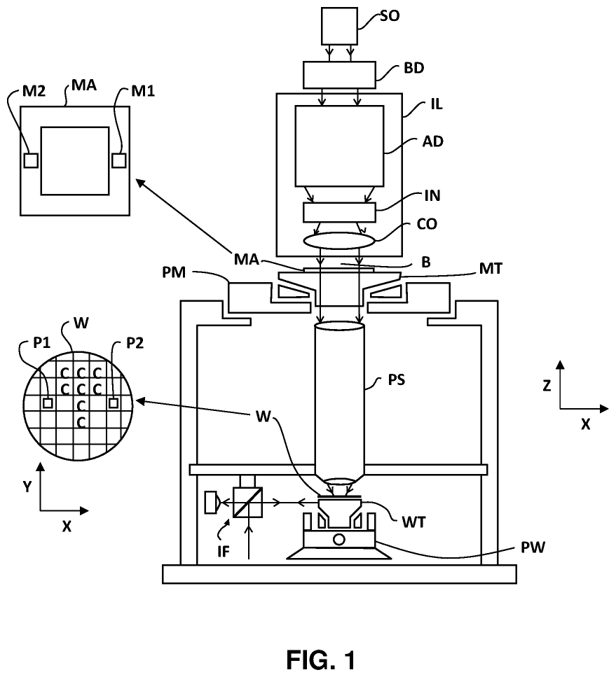

FIG. 1 schematically depicts a lithography apparatus according to an embodiment. The apparatus comprises:
an illumination system (illuminator) IL to condition a beam PB of radiation (e.g. UV radiation or DUV radiation).
a support structure MT to support a patterning device (e.g. a mask) MA and connected to first positioning device PM to accurately position the patterning device with respect to item PL;
a substrate table (e.g. a wafer table) WT for holding a substrate (e.g. a resist coated wafer) W and connected to second positioning device PW for accurately positioning the substrate with respect to item PL; and
a projection system (e.g. a refractive projection lens) PL configured to image a pattern imparted to the radiation beam PB by patterning device MA onto a target portion C (e.g. comprising one or more dies) of the substrate W.

As here depicted, the apparatus is of a transmissive type (e.g. employing a transmissive mask). Alternatively, the apparatus may be of a reflective type (e.g. employing a programmable mirror array of a type as referred to above).

The illuminator IL receives a beam of radiation from a radiation source SO. The source and the lithography apparatus may be separate entities, for example when the source is an excimer laser. In such cases, the source is not considered to form part of the lithography apparatus and the radiation beam is passed from the source SO to the illuminator IL with the aid of a beam delivery system BD comprising for example suitable directing mirrors and/or a beam expander. In other cases the source may be an integral part of the apparatus, for example when the source is a mercury lamp. The source SO and the illuminator IL, together with the beam delivery system BD if required, may be referred to as a radiation system.

The illuminator IL may alter the intensity distribution of the beam. The illuminator may be arranged to limit the radial extent of the radiation beam such that the intensity distribution is non-zero within an annular region in a pupil plane of the illuminator IL. Additionally or alternatively, the illuminator IL may be operable to limit the distribution of the beam in the pupil plane such that the intensity distribution is non-zero in a plurality of equally spaced sectors in the pupil plane. The intensity distribution of the radiation beam in a pupil plane of the illuminator IL may be referred to as an illumination mode.

The illuminator IL may comprise adjuster AM configured to adjust the intensity distribution of the beam. Generally, at least the outer and/or inner radial extent (commonly referred to as σ-outer and σ-inner, respectively) of the intensity distribution in a pupil plane of the illuminator can be adjusted. The illuminator IL may be operable to vary the angular distribution of the beam. For example, the illuminator may be operable to alter the number, and angular extent, of sectors in the pupil plane wherein the intensity distribution is non-zero. By adjusting the intensity distribution of the beam in the pupil plane of the illuminator, different illumination modes may be achieved. For example, by limiting the radial and angular extent of the intensity distribution in the pupil plane of the illuminator IL, the intensity distribution may have a multi-pole distribution such as, for example, a dipole, quadrupole or hexapole distribution. A desired illumination mode may be obtained, e.g., by inserting an optic which provides that illumination mode into the illuminator IL or using a spatial light modulator.

The illuminator IL may be operable alter the polarization of the beam and may be operable to adjust the polarization using adjuster AM. The polarization state of the radiation beam across a pupil plane of the illuminator IL may be referred to as a polarization mode. The use of different polarization modes may allow greater contrast to be achieved in the image formed on the substrate W. The radiation beam may be unpolarized. Alternatively, the illuminator may be arranged to linearly polarize the radiation beam. The polarization direction of the radiation beam may vary across a pupil plane of the illuminator IL. The polarization direction of radiation may be different in different regions in the pupil plane of the illuminator IL. The polarization state of the radiation may be chosen in dependence on the illumination mode. For multi-pole illumination modes, the polarization of each pole of the radiation beam may be generally perpendicular to the position vector of that pole in the pupil plane of the illuminator IL. For example, for a dipole illumination mode, the radiation may be linearly polarized in a direction that is substantially perpendicular to a line that bisects the two opposing sectors of the dipole. The radiation beam may be polarized in one of two different orthogonal directions, which may be referred to as X-polarized and Y-polarized states. For a quadrupole illumination mode the radiation in the sector of each pole may be linearly polarized in a direction that is substantially perpendicular to a line that bisects that sector. This polarization mode may be referred to as XY polarization. Similarly, for a hexapole illumination mode the radiation in the sector of each pole may be linearly polarized in a direction that is substantially perpendicular to a line that bisects that sector. This polarization mode may be referred to as TE polarization.

In addition, the illuminator IL generally comprises various other components, such as an integrator IN and a condenser CO. The illuminator provides a conditioned beam of radiation PB, having a desired uniformity and intensity distribution in its cross section.

The radiation beam PB is incident on the patterning device (e.g. mask) MA, which is held on the support structure MT. Having traversed the patterning device MA, the beam PB passes through the lens PL, which focuses the beam onto a target portion C of the substrate W. With the aid of the second positioning device PW and position sensor IF (e.g. an interferometric device), the substrate table WT can be moved accurately, e.g. so as to position different target portions C in the path of the beam PB. Similarly, the first positioning device PM and another position sensor (which is not explicitly depicted in FIG. 1) can be used to accurately position the patterning device MA with respect to the path of the beam PB, e.g. after mechanical retrieval from a mask library, or during a scan. In general, movement of the object tables MT and WT will be realized with the aid of a long-stroke module (coarse positioning) and a short-stroke module (fine positioning), which form part of the positioning device PM and PW. However, in the case of a stepper (as opposed to a scanner) the support structure MT may be connected to a short stroke actuator only, or may be fixed. Patterning device MA and substrate W may be aligned using patterning device alignment marks M1, M2 and substrate alignment marks P1, P2.

The projection system PL has an optical transfer function which may be non-uniform, which can affect the pattern imaged on the substrate W. For unpolarized radiation such effects can be fairly well described by two scalar maps, which describe the transmission (apodization) and relative phase (aberration) of radiation exiting the projection system PL as a function of position in a pupil plane thereof. These scalar maps, which may be referred to as the transmission map and the relative phase map, may be expressed as a linear combination of a complete set of basis functions. A particularly convenient set is the Zernike polynomials, which form a set of orthogonal polynomials defined on a unit circle. A determination of each scalar map may involve determining the coefficients in such an expansion. Since the Zernike polynomials are orthogonal on the unit circle, the Zernike coefficients may be determined by calculating the inner product of a measured scalar map with each Zernike polynomial in turn and dividing this by the square of the norm of that Zernike polynomial.

The transmission map and the relative phase map are field and system dependent. That is, in general, each projection system PL will have a different Zernike expansion for each field point (i.e. for each spatial location in its image plane). The relative phase of the projection system PL in its pupil plane may be determined by projecting radiation, for example from a point-like source in an object plane of the projection system PL (i.e. the plane of the patterning device MA), through the projection system PL and using a shearing interferometer to measure a wavefront (i.e. a locus of points with the same phase). A shearing interferometer is a common path interferometer and therefore, advantageously, no secondary reference beam is required to measure the wavefront. The shearing interferometer may comprise a diffraction grating, for example a two dimensional grid, in an image plane of the projection system (i.e. the substrate table WT) and a detector arranged to detect an interference pattern in a plane that is conjugate to a pupil plane of the projection system PL. The interference pattern is related to the derivative of the phase of the radiation with respect to a coordinate in the pupil plane in the shearing direction. The detector may comprise an array of sensing elements such as, for example, charge coupled devices (CCDs).

The diffraction grating may be sequentially scanned in two perpendicular directions, which may coincide with axes of a co-ordinate system of the projection system PL (x and y) or may be at an angle such as 45 degrees to these axes. Scanning may be performed over an integer number of grating periods, for example one grating period. The scanning averages out phase variation in one direction, allowing phase variation in the other direction to be reconstructed. This allows the wavefront to be determined as a function of both directions.

The projection system PL of a state of the art lithography apparatus LA may not produce visible fringes and therefore the accuracy of the determination of the wavefront can be enhanced using phase stepping techniques such as, for example, moving the diffraction grating. Stepping may be performed in the plane of the diffraction grating and in a direction perpendicular to the scanning direction of the measurement. The stepping range may be one grating period, and at least three (uniformly distributed) phase steps may be used. Thus, for example, three scanning measurements may be performed in the y-direction, each scanning measurement being performed for a different position in the x-direction. This stepping of the diffraction grating effectively transforms phase variations into intensity variations, allowing phase information to be determined. The grating may be stepped in a direction perpendicular to the diffraction grating (z direction) to calibrate the detector.

The transmission (apodization) of the projection system PL in its pupil plane may be determined by projecting radiation, for example from a point-like source in an object plane of the projection system PL (i.e. the plane of the patterning device MA), through the projection system PL and measuring the intensity of radiation in a plane that is conjugate to a pupil plane of the projection system PL, using a detector. The same detector as is used to measure the wavefront to determine aberrations may be used. The projection system PL may comprise a plurality of optical (e.g., lens) elements and may further comprise an adjustment mechanism PA configured to adjust one or more of the optical elements so as to correct for aberrations (phase variations across the pupil plane throughout the field). To achieve this, the adjustment mechanism PA may be operable to manipulate one or more optical (e.g., lens) elements within the projection system PL in one or more different ways. The projection system may have a co-ordinate system wherein its optical axis extends in the z direction. The adjustment mechanism PA may be operable to do any combination of the following: displace one or more optical elements; tilt one or more optical elements; and/or deform one or more optical elements. Displacement of optical elements may be in any direction (x, y, z or a combination thereof). Tilting of optical elements is typically out of a plane perpendicular to the optical axis, by rotating about axes in the x or y directions although a rotation about the z axis may be used for non-rotationally symmetric aspherical optical elements. Deformation of optical elements may include both low frequency shapes (e.g. astigmatic) and high frequency shapes (e.g. freeform aspheres). Deformation of an optical element may be performed for example by using one or more actuators to exert force on one or more sides of the optical element and/or by using one or more heating elements to heat one or more selected regions of the optical element. In general, it may not be possible to adjust the projection system PL to correct for apodizations (transmission variation across the pupil plane). The transmission map of a projection system PL may be used when designing a patterning device (e.g., mask) MA for the lithography apparatus LA. Using a computational lithography technique, the patterning device MA may be designed to at least partially correct for apodizations.

As lithography nodes keep shrinking, more and more complicated patterning device pattern (interchangeably referred as a mask herein for better readability) are required (e.g., curvilinear masks). The present method may be used in key layers with DUV scanners, EUV scanners, and/or other scanners. The method according to the present disclosure may be included in different aspect of the mask optimization process including source mask optimization (SMO), mask optimization, and/or OPC. For example, a source mask optimization process is described in U.S. Pat. No. 9,588,438 titled “Optimization Flows of Source, Mask and Projection Optics”, which is hereby incorporated in its entirety by reference.

In an embodiment, a patterning device is a curvilinear mask including curvilinear main features and/or SRAFs having polygonal shapes, as opposed to that in Manhattan patterns having rectangular or staircase like shapes. A curvilinear mask may produce more accurate patterns on a substrate compared to a Manhattan pattern. However, the geometry of curvilinear SRAFs, their locations with respect to the target patterns, or other related parameters may create manufacturing restrictions, since such curvilinear shapes may not be feasible to manufacture. Hence, such restrictions may be considered by a designer during the mask design process. A detailed discussion on the limitation and challenges in manufacturing a curvilinear mask is provided in “Manufacturing Challenges for Curvilinear Masks” by Spence, et al., Proceeding of SPIE Volume 10451, Photomask Technology, 1045104 (16 Oct. 2017); doi: 10.1117/12.2280470, which is incorporated herein by reference in its entirety.

Optical Proximity Correction (OPC) is a photolithography enhancement technique commonly used to compensate for image errors due to diffraction and process effects. Existing model-based OPC usually consists of several steps, including: (i) derive a target pattern including rule retargeting, (ii) place sub-resolution assist features (SRAFs) within the target pattern, and (iii) perform iterative corrections including patterning process model simulations. The OPC process is highly time consuming and may further require cleanup based on mask rule check (MRC), simulation of mask diffraction, optical imaging, and resist development. The mechanisms provided herein can expedite generation of a final mask pattern that complies with MRC, thereby improving the existing technology.

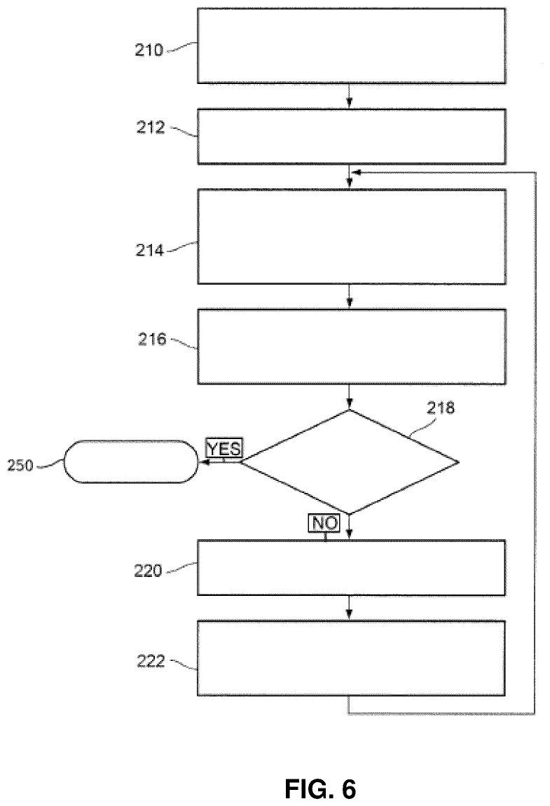

Details of techniques and models used to transform a patterning device pattern into various lithographic images (e.g., an aerial image, a resist image, etc.), apply OPC using those techniques and models and evaluate performance (e.g., in terms of process window) are described in U.S. Patent Application Publication Nos. US 2008-0301620, 2007-0050749, 2007-0031745, 2008-0309897, 2010-0162197, 2010-0180251, and 2011-0099526, the disclosure of each which is hereby incorporated by reference in its entirety. Another model-based OPC technique is also discussed in US patent U.S. Pat. No. 8,812,998 B2, which is incorporated herein by reference in its entirety. An example model-based OPC method is also discussed herein with respect to FIGS. 6-9E.

A mask pattern design process involving determining OPC is hardly a local effect problem that is limited to a particular mask feature. Rather, OPC typically is a non-linear short range (ambit) problem, where within an ambit there may be a plurality of mask features affecting OPC solution related to each other. In other words, a portion of mask feature may affect another portion of a nearby mask feature. Thus, nearby mask features dictate the OPC solution convergence and quality. In an embodiment, the portions of mask features may be represented as segments. However, defining a segment and associated local effect on an OPC solution is difficult, particularly in freeform (e.g., curvilinear) masks. For an optimum OPC solution, several evaluation-points may be assigned to the mask features to evaluate effects of changes in the mask features. Moreover, a multivariable solver (MVS) is preferred, for example, in situations with high mask error enhancement factor (e.g., MEEF>1).

Existing OPC determination methods employing image-based optimization are computationally intensive. A single variable solver (SVS) usually does not achieve a global optimum OPC solution. In addition, performing SVS based OPC optimization on spline control points domain is challenging. In order to address such issues with exiting methods, the present disclosure provides mechanisms for optimizing a mask, especially a freeform mask, that simplifies the problem/optimization and can be embedded into the MVS. It also achieves a sweet spot between the computation cost and ability to achieve global optimum OPC solution and faster convergence to optimum solution.

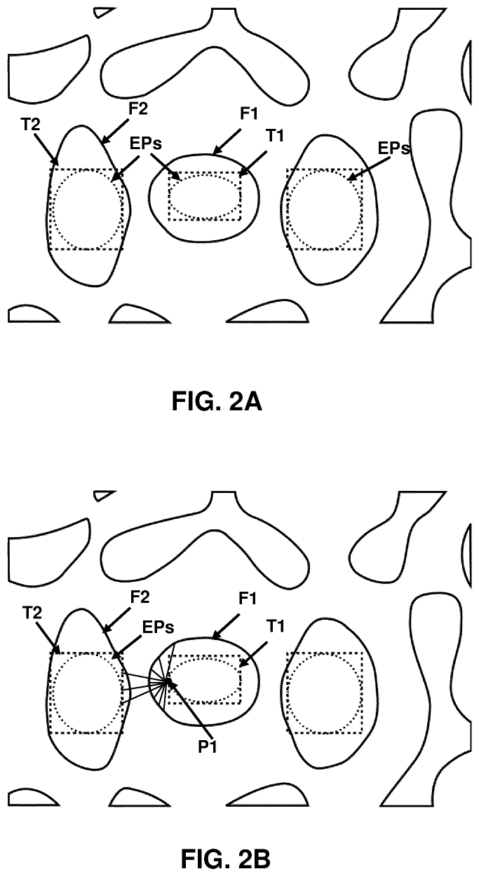

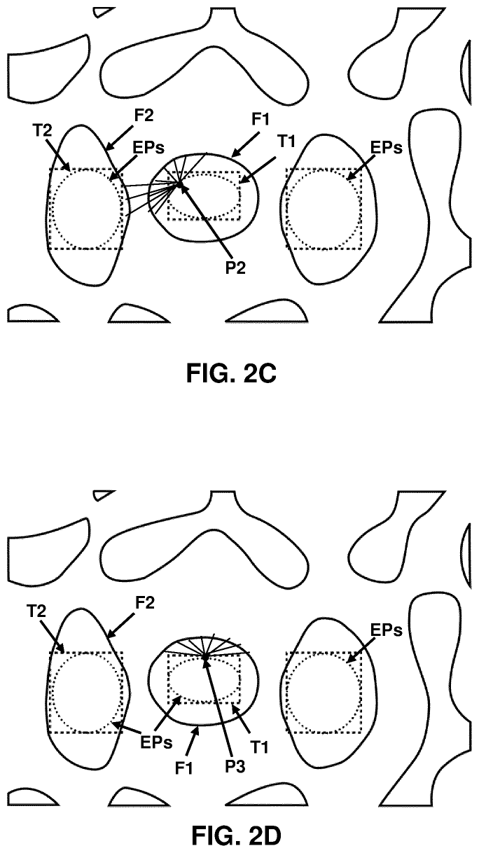

In an embodiment, the MVS variables may correspond to multiple segments of one or more mask features. During OPC simulation, all these segments may be adjusted together, so that collectively such adjustment generates an optimum overall solution. For example, if some segments are competing with each other and a SVS is employed, movement of these segments may conflict with each other and OPC simulation may not converge. On the other hand, an MVS can find a local minima that is reasonable (e.g., within an acceptable limits) by sacrificing or restricting movements of different segments with respect to each other to achieve the optimum global solution. The effect of different segments of a mask feature on other mask features is discussed in more detail with respect to FIGS. 2A-2D. The present mechanism enables less complex freeform optimization while extending MVS thereby achieving faster converging optimum freeform mask patterns.

FIG. 2A illustrates an exemplary freeform mask pattern comprising curved mask features such as F1 and F2. In an embodiment, the mask pattern may be obtained using any suitable method, e.g., physics based freeform simulation, machine learning model configured to generated curved mask pattern, continuous transmission mask (CTM) methods, or other mask generation method. In an embodiment, the mask pattern in FIG. 2A may be generated by applying a curvature function to convert a target pattern into a curved pattern. The mask pattern in FIG. 2A may serve as starting point for OPC simulation to generating a finalized mask pattern through an optimization process. For example, during the simulation evaluation points EPs (dots) may be used to evaluate the effect of changing the shape of mask features. In an embodiment, such effect may be evaluated in terms of a performance metric such as an edge placement error (EPE) of a substrate contour with respect to a target contour. In FIG. 2A, target features T1 and T2 (dashed lines) and evaluation points EPS (dots) are superimposed on the mask features F1 and F2 for visual reference.

FIGS. 2B-2D illustrate how different portions of a mask feature affect printing of features at locations represented by evaluation points EPs. For example, in FIGS. 2B, printing at an evaluation point P1 (amplified for visual reference) is affected by characteristics (e.g., curvature, location, etc.) of a portion of the mask feature F1 and surrounding portions of adjacent mask feature F2. For example, a performance metric such as EPE at evaluation point P1 is affected by mask feature portions at distances indicated by lines drawn from point P1 to different portions of the mask features F1 and F2. Similarly, in FIGS. 2C, an evaluation point P2 (amplified for visual reference) is affected by characteristics of portions of the mask feature F1 and the mask feature F2. In FIG. 2D, an evaluation point P3 is affected by a portion of only the mask feature F1, but not the mask feature F2.

As illustrated in FIGS. 2B-2D, all or a few curved mask features may affect printing at a certain evaluation point associated with the mask feature F1. Similarly, all or a few curved mask features may affect printing at another set of evaluation points (e.g., associated with the feature F2). To incorporate such effects, performing OPC becomes a complex global problem, and not simply a local problem (e.g., local to one evaluation point). In some examples, a single evaluation point may be affected by mask features nearby (e.g., within a defined ambit), which makes it a global problem. In some examples, a single mask feature affects all evaluation points nearby (e.g., within a defined ambit), which makes it a global problem.

Embodiments provide mechanisms to enable OPC to handle cross effects caused by adjacent features. For example, OPC may cause a portion of mask feature F2 to come so close to a portion of the mask feature F1 that the cross effect increases. During OPC, an increase in cross effect may cause different portions of the mask feature F1 to move away from the feature F2. Hence, the OPC problem is a highly nonlinear problem that is solved using an iterative approach. The OPC problem is further complicated when determining the freeform mask pattern because it is difficult to dissect a curved feature in different curved segments so that during OPC these segments may be moved to generate optimized mask pattern. For example, the difficulty lies in defining how to start dissecting the curved feature and determining which segment has a particular effect in another region of a mask pattern.

In an embodiment, the challenges in OPC are tackled by approximating a freeform mask pattern into a segmented mask pattern (e.g., staircased mask pattern). This simplifies corrections to be applied during the OPC simulation. Further, the freeform representation is represented by embedding a smoothing function (e.g., a Gaussian convolution) along with the segmented mask pattern representation inside the OPC model process, e.g., the iterative simulation process. Such embedded smoothing function advantageously makes the segmented mask pattern continuous (e.g., curved), while the segmentation enables use of Jacobian computation in an MVS with the curved mask pattern.

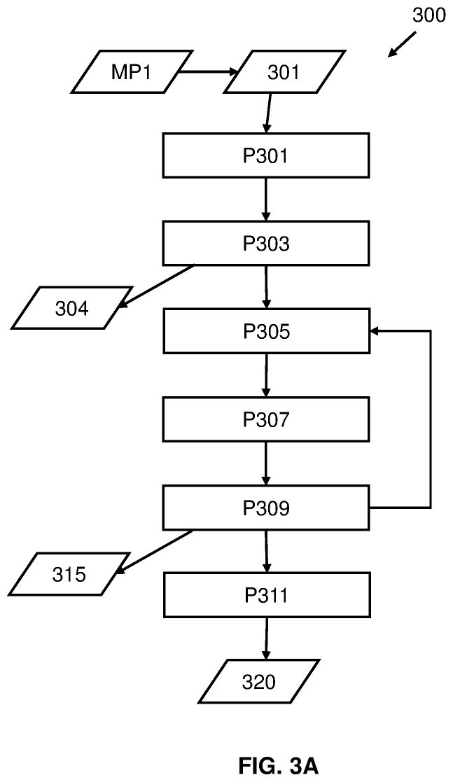

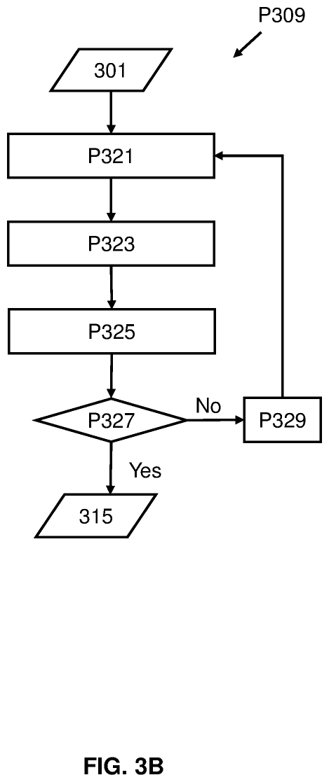

FIG. 3A is a flow chart of an exemplary method 300 for generating a mask pattern for a lithography process according to an embodiment of the present disclosure. The method 300 involves approximating an initial mask pattern into a segmented mask pattern, and applying a smoothing function to the segmented mask pattern. The generation of the mask pattern may include an iterative optimization process. In each iteration, the segmented pattern is adjusted and smoothed, and the smoothed mask pattern is used to perform a simulation process (e.g., OPC simulation executing patterning process models) to determine the lithographic performance. Thus, advantageously, in each iteration, segments of a mask feature may be adjusted, while the smoothing function converts the segmented or adjusted mask features into a smoothed feature so that the OPC simulation is performed on a freeform mask pattern. This can significantly reduce the computational time and resources, as well as generate an accurate mask pattern. An example implementation of the method is discussed with respect to processes P301, P303, P305, P307, and P311.

Process P301 involves accessing a first segmented mask pattern 301 comprising a plurality of segmented features of a first mask pattern MP1. In an embodiment, accessing the first segmented mask pattern 301 involves accessing the first mask pattern MP1 comprising a plurality of features; and converting the first mask pattern MP1 into the first segmented mask pattern 301 by segmenting a feature of the plurality of features into a plurality of segments. In an embodiment, each segment may be a line. In an embodiment, the first mask pattern MP1 comprises a plurality of curved features. Accordingly, the plurality of segmented features of the first segmented mask pattern 301 may correspond to the plurality of curved features. In an embodiment, the first mask pattern MP1 may be obtained by one or more of simulating a patterning process, an inverse lithography process, a machine learning model configured to generate a curved mask pattern, an all-angle OPC process, a continuous tone mask (CTM), or CTM and CTM+ mask pattern generation process, or other mask pattern generation process.

In an embodiment, the converting of the first mask pattern MP1 involves approximating the feature of the first mask pattern MP1 into the plurality of segments, where each segment may be oriented at a desired angle (e.g., 30°, 45°, 60°, 90°, or any arbitrary angle etc.) with respect to an adjacent segment. In an embodiment, the converting involves dissecting the feature of the first mask pattern MP1 into the plurality of segments to generate staircased features, where each segment is oriented at approximately 90° angle with respect to an adjacent segment. For example, the converting step includes tracing a curve of the mask feature and approximating the curve by Manhattan lines with a minimum deviation between the curve and the Manhattan line.

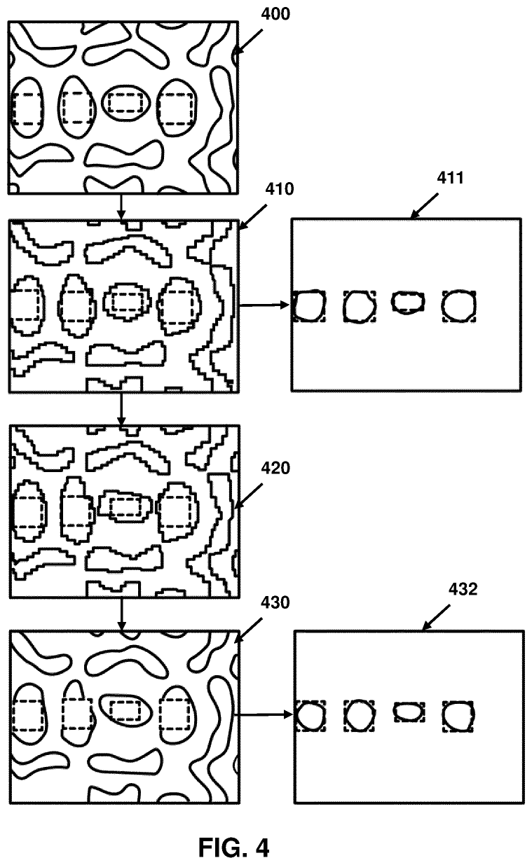

FIG. 4 illustrates an example of segmented mask pattern 410 of a first mask pattern 400. For example, the first mask pattern 400 may be obtained from a machine learning model configured to generate curvilinear mask patterns, e.g., using a target pattern as input. The curvilinear mask pattern may include main features corresponding to the target pattern (e.g., dotted rectangular shapes superimposed on some mask features at the center of the mask pattern 400 for visual reference). In an embodiment, the curvilinear mask pattern may also include assist features such as SRAFs (not illustrated for simplicity). The curvilinear mask features of the mask pattern 400 may be segmented into Manhattanized features by tracing the curve of each mask features in the mask pattern 400 to generate the segmented mask pattern 410. Advantageously, such segmentation simplifies the issue related to determining portions of a curved features that need to be adjusted during OPC simulation for finalizing a mask pattern. For example, adjusting (e.g., moving up, down, left, right) one or more straight lines or segments is relatively simpler than moving a curved mask features without distorting the shape of the mask features significantly. Adjusting the segments may be desired since a simulated contour 411 (curved features) of target features (dotted rectangles) to be printed a substrate may not meet a performance specification (e.g., EPE).

Referring back to FIG. 3A, process P303 involves generating a smoothed representation 304 of the first segmented mask pattern 301 by applying a first smoothing function. In an embodiment, the first smoothing function may be a Gaussian function, a filter such as a low pass filter, smoothing splines, or other smoothing functions that allow conversion of segmented features into approximately smoothed features with minimum deviation from the original segmented features. As an example, the smoothed representation 304 may be generated by convoluting the segmented representation with a Gaussian function, where the Gaussian function comprises shaping parameters that are tuned to approximate a segmented shape to a curved shape, e.g., with minimum deviation between contours of the curved shape and the segmented shape.

Process P305 involves adjusting the first segmented mask pattern 301 with a set of changes to one or more of the plurality of segmented features. In an embodiment, the adjusting involves changes to one or more main features (e.g., corresponding to target features), and assist features (e.g., SRAF and sub-resolution inverse features (SRIF)) of the first segmented mask pattern 301; changes to one or more assist features of the first segmented mask pattern 301; or simultaneously changing both the main features and the assist features of the first segmented mask pattern 301.

In an embodiment, the changes include movement of segments of boundaries of the features. In an embodiment, the changes include changes of shapes of the features. In an embodiment, the changes include changes of locations of the features. In an embodiment, the adjusting is performed under constraints dictating a range of at least some of the changes to the plurality of segmented features. Examples of adjusting of segments are further discussed with respect FIGS. 6-9E and further discussed in detail in U.S. Pat. No. 8,812,998 B2, which is incorporated herein by reference in its entirety.

Process P307 involves evaluating the smoothed representation 304 by simulating a patterning process using the smoothed representation 304 of the adjusted segmented mask pattern. In an embodiment, the evaluating of the smoothed representation 304 involves determining whether the simulation results satisfy a termination condition associated with the patterning process, where the simulation results are generated when the set of changes is made to the one or more of the plurality of segmented features.

In an embodiment, the evaluation involves placing evaluation points on the segments of the plurality of features, and evaluating the cost function over all of the evaluation points. In an embodiment, the evaluating involves evaluating a cost function that measures the impact on a lithographic metric from the set of changes to the plurality of segmented features for a plurality of lithographic process conditions. It will be appreciated that the any suitable evaluation metric can be used in the cost function without departing from the scope of the present disclosure. For example, the evaluation metric may be a lithographic metric EPE, CD, edge placement, overlay etc., which in turn can be calculated or represented in any suitable type of simulated or measured signals or parameters, such as signals of resist images, aerial images, or etch images. In an embodiment, the cost function may be a function of at least one of: relative alignment of at least a pair of the plurality of segmented features, magnitudes of the changes to the plurality of segmented features, and characteristics of a resist image or an aerial image. It can be understood that the aforementioned cost functions are only exemplary and do not limit the scope of the present disclosure. In an embodiment, the cost function may be a function of a probability of a function of the features and a process window defined by the plurality of lithographic process conditions having a value outside a permitted range. In an embodiment, the plurality of lithographic process conditions may include a plurality of different focus and dose values. A person of ordinary skill in the art may employ other cost functions used in semiconductor manufacturing (e.g., related lithography process) that can be represented as a function of a simulation result generated using a smoothing function therein. For example, the cost function may be a function of one or more of the following lithographic metrics: edge placement error, critical dimension uniformity, dose variation, focus variation, process condition variation, mask error (e.g., MEEF), mask complexity, resist contour distance, worst defect size, best focus shift, and mask rule constraint.

In some embodiments, EPE corresponds to the distance from an evaluation point to a contour of the simulated resist image, and thus the cost function can evaluate the resist image directly, represented as follows.

$$CF = {\sum }_{i = 0}^{N} {RI ( AI ( S ( {MI}^{′} ) ) )}_{i} \qquad ( Eq . 3.1 )$$

In the above equation, CF represents an exemplary cost function, i represents evaluation points, M1′ is a representation of a segmented mask, and S( ) represents a smoothing function. Accordingly, S(MI′) represents a smoothed represented of the segmented mask pattern. The term MI( ) represents a mask image function or model that generates a mask image from the smoothed mask pattern. The term RI( ) represents a resist image function or model that generates the resist image from the mask image. The exemplary cost function CF shows that resist image may be obtained using a resist model on aerial images, which can be generated by using an optical model on a smoothed mask pattern of the segmented mask pattern. For example, any adjustment in the segmented mask pattern, impacts the smoothed mask pattern and eventually the resist image. In this example, the lithographic metric may be a resist image characteristics (e.g., EPE computed based on contours extracted from resist image, pixel intensity values, image slope, etc.). Thus, the cost function can be evaluated, in terms of the resist image generated from the smoothed mask pattern, when any segment of the segmented mask pattern is adjusted. In an embodiment, the cost function CF above may be used in the methods discussed with respect FIG. 6-9E and further discussed in the U.S. Pat. Nos. 8,812,998 B2 and 8,560,979, which are incorporated herein by reference in its entirety.

In an embodiment, the evaluating of the smoothed mask pattern involves calculating a Jacobian matrix. The Jacobian matrix comprises a set of derivatives of a function of the smoothed representation 304 with respect to the plurality of segments of the first segmented mask pattern 301. In an embodiment, the Jacobian matrix serves as a guide to adjusting the segments of the segmented mask pattern. For example, Jacobian matrix quantifies an impact of an adjustment of a segment on the resist image, which is indicative of a pattern to be printed on the substrate. In this example, the resist image may be represented as a pixelated image and may be evaluated based on changes in the resist image characteristics (e.g., pixel intensity values, image slope, etc.) from adjustments to the segmented mask pattern. In an embodiment, the adjustment may be an iterative process, as such by computing the Jacobian matrix, the first segmented mask pattern 301, or a segmented mask pattern in a subsequent iteration may be adjusted until a desired cost function threshold is reached, a threshold number of iterations is reached, or other termination conditions are satisfied.

Computing Jacobian matrix based on a segmented mask pattern is advantageous compared to computing Jacobian directly on a first mask pattern MP1 having curved features. For example, computing the Jacobian guided by segmented mask pattern is easier and computationally less expensive compared to directly computing a Jacobian on a curved mask pattern.

In an embodiment, the Jacobian may be computed as follows:

$$J = \frac{\partial RI}{\partial d} = [ \begin{matrix}\frac{\partial {RI}_{0}}{\partial {d}_{0}} & … & \frac{\partial {RI}_{0}}{\partial {d}_{M}} \\ ⋮ & ⋱ & ⋮ \\ \frac{\partial {RI}_{N}}{\partial {d}_{0}} & … & \frac{\partial {RI}_{N}}{\partial {d}_{M}}\end{matrix} ] \qquad ( Eq . 3.2 )$$

In the above equation, J represents the Jacobian matrix which is computed as a partial derivative of a resist image RI with respect to a segment d of the mask pattern. For example, the resist image may be computed, as represented by RI(AI(S(MI′)))ᵢ. Accordingly, the Jacobian may be computed for a smoothed segmented mask S(MI′). The terms N represents a number of evaluation points, and M represents a number of segments of a segmented mask pattern.

In an embodiment, the simulating of the patterning process involves executing an MVS

implementing the cost function and the Jacobian matrix to generate a freeform mask pattern. For example, the location of each segment in the direction perpendicular thereto is denoted as CVₖ, k=1, . . . , M, wherein M is the total number of segments on the mask or a portion of the mask. The location of each segment can also be represented as a change relative to the initial location of the segment. Namely, dCVₖ=CVₖ−CVₖ⁰, wherein CVₖ⁰ is the initial location of the k-th segment and dCVₖ is the change relative to the initial location CVₖ⁰. The location may be represented in a vector format as discussed with respect to FIG. 6A. A Jacobian of a lithographic metric such as characteristic of a resist image may be computed with respect to CV. For example, EPE computed from contours of the resist image (e.g., RI(AI(S(MI′)))ᵢ) obtained using the smoothed representation of the segmented pattern. The Jacobian matrix can be calculated in every iterative step, or calculated in one iterative step and used in several succeeding iterative steps.

An exemplary cost function that measures an impact of the lithographic metric from changes to the main features and assist features characterized by CV or dCV can be defined as equation Eq. 1, see discussion with respect to FIG. 6 at step 222. The cost function may be expanded using the Jacobian matrix, as shown by equation Eq. 2, see discussion with respect to FIG. 6 at step 222. In an embodiment, the approximated cost function can then be minimized by quadratic programming.

Specifically, a value of dCV that yields a minimum of CF in the vicinity of CV^{q}, which is denoted as dCV^{q}, can be derived by omitting the last term of Eq. 2 and solving M linear equations of ∂CF/∂CVₖ=0.

In an embodiment, by employing MVS in an iterative manner in the OPC simulation using smoothing embedded OPC model, a final convergence may be achieved when the smoothed mask contour converges to the target pattern. In an embodiment, such final convergence is achieved even though the optimizing is performed using the segments (e.g., staircase segments) of the segmented mask pattern.

Advantageously, by applying the smoothing to the segmented mask pattern MI′ (e.g., (S(MI′)), the Jacobian computation can quantify each segment's impact at the evaluation points resulting in fast convergence of OPC solution. For example, adjusting of the segments is performed along with evaluating the cost function using the Jacobian matrix so that a value of the cost function is caused to be within a desired threshold range (e.g., desired EPE range or RI signal values). In an embodiment, the adjusting is performed iteratively until the cost function is minimized.

In an embodiment, depending on the form and formula of the cost function, the termination condition may include one or more of: minimization of the cost function; maximization of the cost function; reaching a preset number of iterations; reaching a value of the cost function equal to or beyond a preset threshold value; reaching a predefined computation time; and reaching a value of the cost function within an acceptable error limit.

Process P309 involves obtaining, based on the adjusted segmented mask pattern, a resultant segmented mask pattern 315. The obtaining of the resultant segmented mask pattern 315 may be an iterative process involving simulating of the patterning process that includes process models configured to apply the smoothing function to the segmented mask pattern. In an embodiment, the obtaining of the resultant segmented mask pattern 315 is an iterative process involving processes P305, and P307 in each iteration. FIG. 3B is an exemplary implementation of obtaining the resultant segmented mask pattern 315. For example, the process P309 involves processes P321, P323, P325, P327, and P329. The process P321 involves adjusting the first segmented mask pattern 301 with a change (e.g., a first change in a first iteration, a second change in a second iteration, etc.) of the set of changes of the more or more of the plurality of segmented features. The process P323 involves generating, using the first smoothing function, the smoothed representation of the adjusted segmented mask pattern. The process P325 involves simulating a patterning process (e.g., including an optical model, and a resist model) using the smoothed representation of the adjusted segmented mask pattern. For example, the simulation (e.g., RI(AI(S(MI′))) involves executing the resist model RI, the optical model AI using the smoothed mask representation (e.g., S(MI′)) that results in the resist image. The simulation results are globally evaluated based on the adjusted segmented pattern. For example, a Jacobian of a simulation result (e.g., RI) is computed, employed in conjunction with a cost function to determine impact of one or more adjustments on the RI and the cost function.

The process P327 involves determining whether the simulation results or characteristics associated with the simulation results (e.g., resist image) satisfy a termination condition. The process P329 involves responsive to the termination condition not being satisfied, adjusting, based on the evaluation at process P327, the first segmented mask pattern 301 with a second change of the set of changes of the one or more of the plurality of segmented features so that the subsequent iteration converges (e.g., satisfies a termination condition). The processes P321-P329 are repeated until a termination condition is satisfied. For example, in a second iteration, the second change creates a second segmented mask pattern that can be used in steps P323-P329 in place of the first segmented mask pattern 301, and until the termination condition is satisfied. For example, the termination condition may be minimization of the cost function CF based on the Jacobian matrix.

Referring back to FIG. 3A, process P311 involves generating, based on a second smoothing function and the resultant segmented mask pattern 315, a mask pattern 320 having smoothed features. In an embodiment, the second smoothing functions may be a Gaussian function, a filter such as a low pass filter, smoothing splines, or other smoothing functions that allow conversion of segmented features into approximately smoothed features with minimum deviation from the original segmented features. In an embodiment, the first smoothing function and the second smoothing function are the same functions.

The method 300 has several advantages. For example, starting from a segmented (e.g., staircased) version of a freeform mask pattern saves significant runtime and allows more alignment with final freeform mask pattern to be generated. Using a segmented version enables controlling a number of partitions to be created for a mask pattern, which helps to limit the Jacobian matrix and cost function sizes, for example, thereby boosting computing performance. Based on example simulation runs, the results from present method demonstrate significant improvement over existing methods. For example, approximately 5 to 20 evaluation points assignment were good enough for evaluation purposes. Within 4 iterations, for example, sufficient convergence towards final mask pattern was achieved. The runtime was significantly less that CTM+ iterations.

Furthermore, the method 300 provides advantages related assist feature handling. For example, optimization of SRAFs locations within the mask pattern may not be necessary, but it may be possible if needed. Print avoidance of SRAFs can be handled using segmented SRAFs. Such avoidance check can be very fast as SRAF segments may only move if nearby image pixels show SRAF printing in a simulated contour of a substrate. Both connected and disconnected SRAFs to a main feature can be handled in the OPC simulation using smoothing embedded segmented mask patterns.

FIG. 4 illustrates an example of generating the mask pattern using the method 300. An initial mask pattern 400 may be obtained via a machine learning model, or other mask pattern generation methods. As discussed in process P301, the segmented mask pattern 410 of the initial mask pattern 400 may be generated. For example, staircasing may be applied to features of the mask pattern 400 to generate the segmented mask pattern 410 having segmented features as shown in solid lines. In an embodiment, such segmented mask pattern 410 may not be directly employed to printing target pattern on a substrate because simulated contours (e.g., contours in a resist image) of the substrate determined by an OPC simulation using the segmented mask pattern 410 may not satisfy performance specification with respect to the target pattern. For example, the simulated image 411 shows that the simulated contours may not satisfy EPE specification with respect to the target features (depicted in dotted lines for visual reference). A further optimization may be desired by adjusting one or more of the segmented features of the segmented mask pattern 410 to cause the simulated contour of the substrate to satisfy the performance specification.

In an embodiment, as discussed in the processes P303 and P305, adjustments to the segmented mask pattern 410 may be performed by embedding a smoothing function in a cost function or other metric used during the OPC simulation. Thus, although segments are moved, the computation of resist image and cost function, for example, are based on smoothened version of the segmented mask pattern 410. Also, as further explained at the processes P307 and P309, the adjustments to the segmented mask pattern 410 may be performed iteratively to generate a resultant mask pattern 420. The adjustment of segmented mask patterns advantageously provides easier cost function, and Jacobian computations thereby saving significant computational time and resources.

The resultant mask pattern 420 also includes segmented features as shown. The resultant mask pattern 420 is obtained when a termination condition in the OPC simulation is satisfied. In other words, the resultant mask pattern 420 includes adjusted segments of mask features that cause the performance specification of a patterning process to be satisfied. For example, using the resultant mask pattern 420 ensures that simulated contours in the resist image are within desired EPE specification.

In an embodiment, the resultant mask pattern 420 may be further smoothened using the second smoothing function, as explained in the process P311, to generate a smoothed mask pattern 430. For example, a Gaussian function may be convoluted with the resultant mask pattern 420 to convert the segmented features into curved features. Thus, a final mask pattern 430 comprising curved features may be generated from the resultant mask pattern 420. When the final mask pattern 430 is used to simulate contours of a substrate, a good match with the target pattern is obtained. For example, a simulated image 432 illustrates the simulated contours (solid lined curved features) within acceptable limits of the target features (dotted rectangles).

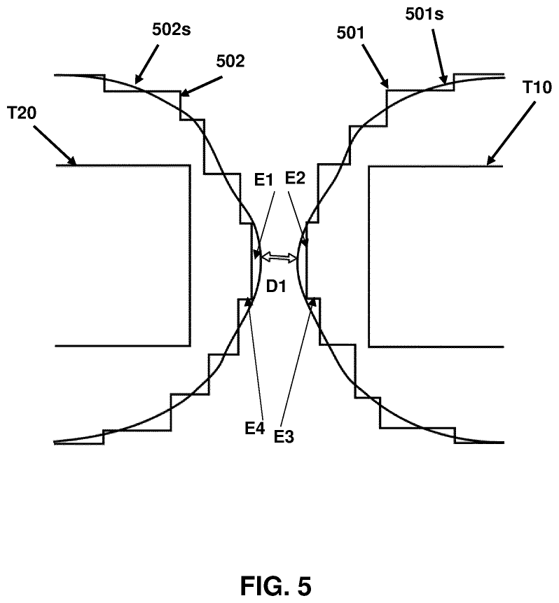

FIG. 5 illustrates an exemplary integration of mask rule check (MRC) in the process of generating a mask pattern, according to an embodiment of the present disclosure. In the present example, a mask pattern may include segmented features 501 and 502 corresponding to target features T10 and T20, respectively. In an embodiment, MRC can be performed on smoothened version 501s and 502s (e.g., obtained by applying the first smoothing function) of the segmented mask features 501 and 502, respectively. For example, a distance DI check between the smoothened features 501s and 502s may be performed. Upon MRC violation (e.g., distance DI breaches a distance threshold), the segments close to the location of MRC violation may be adjusted. For example, segments E1, E2, E3, and E4 close to the distance DI are adjusted. In an embodiment, the cost function may be updated to include an MRC violation penalty term to automatically account for MRC violations. Accordingly, when a final mask pattern is generated, it automatically satisfies MRC. Advantageously, such MRC based adjustments to the segmented features 501 and 502 prevents pinch or bridge formation between mask features.

In an embodiment, the method 300 may be further extended to include additional features. For example, the method may perform repair or adjustments at locations having poor predictions related to main feature shapes, or SRAF placement issues. For a process window, hot spot locations due to poor SRAFs predictions from an existing OPC process may be identified. Such hot spots may be detected based on a cost function value and reported during the simulation process. For example, hot spots refer to locations where the cost function value is above a desired threshold indicating that such locations of the mask pattern will likely result in printing features on a chip that will not meet the design specification (e.g., CD, or overlay specification). The method can then treat non-converging areas as repair regions. Based on such repair regions, new SRAFs may be generated in empty areas (e.g., in case of missing SRAFs), but not necessarily in optimum locations within the mask pattern. Additionally, evaluation points may be assigned within a search window to capture new SRAFs. During simulation, based on the evaluation points, SRAF locations for such hot spots may be optimized.

In another example, one or more mask features may be marked or tagged to enable mix and match freeform solution together with Manhattan solution. In yet another example, the method may only perform partial segmentation of a curved mask pattern. Accordingly, only few polygons may be segmented (e.g., Manhattanized) and few may have curved shape. In an embodiment, such partial segmentation may be based on user-input or identified hotspots.

In an embodiment, the method 300 provides additional advantage in terms of boundary handling for segmented features. For example, during simulation only some portions of mask feature may be moved so the features may be broken and may need rejoining of the portions of the mask features. Such joining of the portions is simpler in case of staircased pattern, for example, as the portions may be joined by simply extending the adjacent segments. However, for curved mask pattern it may be more challenging. The present method with its embedded smoothing provides a forward simulation which ensures seamless interfaces between adjusted portions of the mask features.

In an embodiment, the method may be further extended to recognize similar design patterns and deal with them in a similar manner to generate more consistent mask patterns. Similarly, the design patterns may be configured in a hierarchy and accordingly generate mask patterns.

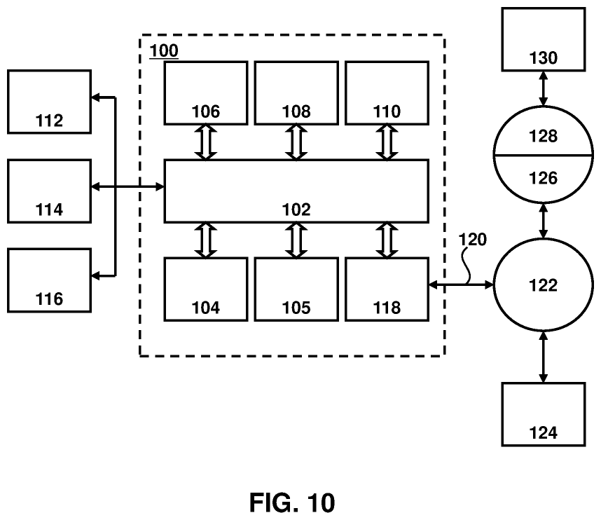

In an embodiment, the methods discussed herein may be provided as a computer program product or a non-transitory computer readable medium having instructions recorded thereon, the instructions when executed by a computer implementing the operation of the methods 400 and 900 discussed above. An example computer system 100 in FIG. 10 includes a non-transitory computer-readable media (e.g., memory) comprising instructions that, when executed by one or more processors (e.g., 104), cause operations including steps of the method 300 discussed herein.

In the following description, equations may be modified according to the method 300. For example, the cost functions and Jacobian matrix equations (e.g., Eq. 1-Eq. 5) may be modified and defined as a function of a lithographic metric resulting from a simulation process (e.g., using RI, AI, MI, model etc.) performed using a smoothing function as explained with respect to equations Eq. 3.1 and 3.2. Accordingly, the following description provides another exemplary implementation of methods for improving mask pattern generation that may be developed independently to integrated with the method 300.

FIG. 6 is a flowchart showing an existing model-based OPC design process. In step 210, a pre-OPC layout, an OPC technology file, an optical model, and a resist model are obtained. The OPC technology file describes the types of model-based OPC techniques that are to be used, for example linewidth bias corrections, corner rounding corrections, or line end pull back corrections. The optical model describes the illumination and projection optics of the exposure tool. The optical model may also include the effect of imaging into a thin-film resist or the effect of the mask topography. The resist model describes the changes in the resist after being illuminated by the mask pattern in the exposure tool. An etch model may also be used in the method of FIG. 6. The optical, resist, and etch models can be derived from first principles, determined empirically from experimental data, or a combination of both. The models are usually calibrated at the nominal process condition. See R. Socha, “Resolution Enhancement Techniques”, Photomask Fabrication Technology, Benjamin G. Eynon, Jr. and Banqiu Wu, Editors, McGraw-Hill, pp. 466-468, 2005. The pre-OPC layout, the OPC technology file, and the models are all inputs to the model-based OPC software.

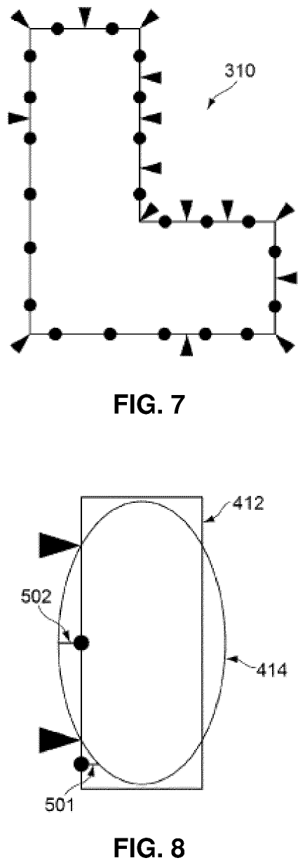

In step 212, the model-based OPC software dissects the features in the pre-OPC layout into edge segments and assigns control points to each edge segment. Each feature is dissected prior to applying any OPC techniques because each feature, even identically-shaped features, will be subject to different proximity environments. The control points (or evaluation points) are the locations where CD or edge placement errors (EPE) will be evaluated during the OPC design process. The assignment of the control points is a complex process that depends on the pattern geometry of the pre-OPC layout and the optical model. FIG. 7 shows an L-shaped feature 310 with dissection points represented by triangles and assigned control points represented by circles.

In step 214, the model-based OPC software simulates the printed resist image on the wafer by applying the optical model and the resist model to the pre-OPC layout. In general, the simulation is performed at the nominal process condition at which the optical model has been calibrated. In step 216, the model-based OPC software generates the contours of the simulated resist image by comparing the simulated resist image values to a predetermined threshold value. The model-based OPC software then compares the simulated contours with the pre-OPC layout at all of the control points to determine if the design layout will deliver the desired patterning performance. The comparisons are typically quantified as a CD or an EPE at each control point. In step 218, the model-based OPC software determines whether a figure of merit for the contour metric of each edge segment is satisfied. In one embodiment, the figure of merit is satisfied when the total error for the contour metric, e.g., CD or EPE, of each edge segment is minimized. In another embodiment, the figure of merit is satisfied when the total error for the contour metric of each edge segment is below a predetermined threshold. If the figure of merit is satisfied the process ends at step 250, but if the figure of merit is not satisfied, the process continues with step 220.

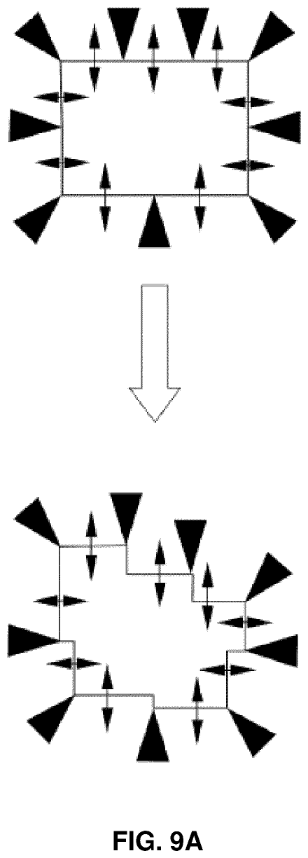

FIG. 8 shows two EPEs with opposite signs measured at two control points. If an assumed simulated resist image contour 414 does not overlap the feature's designed geometry 412 at the control point, then the EPE is determined based on the difference at that control point. Returning to FIG. 6, in step 220 the model-based OPC software calculates the edge correction amount at each control point. If it is assumed that the EPE of the i-th edge segment (Eᵢ) is ΔLᵢ determined at control point Cᵢ, the simplest edge correction amount ΔLᵢ is a negation of the error: ΔLᵢ=−ΔLᵢ. Such a straightforward correction function does not work well for non-linear processes because changes on the mask are not linearly reflected in the printed resist image. To account for nonlinearities such as the mask error factor (MEEF), a slightly more complicated correction function can be used such as

$$Δ {L}_{i} = - \frac{Δ {E}_{i}}{MEEF} .$$

Application of the method of calculating the appropriate correction in a production mask is quite complex, and the correction algorithms can depend on factors such as linewidth error, fabrication process, correction goals, and constraints. See A. K. Wong, Resolution Enhancement Techniques in Optical Lithography, SPIE Press, pp. 91-115, 2001. For example, if it is assumed that there are N edge segments of a feature and one control point for each edge segment, and that the correction amount for the i-th edge segment is ΔLᵢ the ultimate goal is to solve for ΔL₁, ΔL₂, . . . , ΔL_{N}, such that the difference between resist image values RI(Cᵢ) and the predetermined threshold values T at all control points are equal to zero as: RI(Cᵢ)−T=0 for i=1, . . . , N, where Cᵢ are the control points. Or minimize the function Σᵢ₌₁^{N}[RI(Cᵢ)−T]².

Next, in step 222, the model-based OPC software adjusts the entire edge segment Eᵢ according to the calculated correction amount ΔLᵢ for all edge segments to produce a post-OPC layout, such that the simulated resist image contour moves to match the design geometry. Then the method returns to step 214, where the model-based OPC software simulates a resist image using the post-OPC layout produced in step 222. The resist image contours and error are then calculated for the simulated resist image produced using the post-OPC layout in step 216. In step 218 the model-based OPC software determines whether a function that measures the EPE is minimized or below a certain threshold. Such a function is usually referred to as a “cost function”. An exemplary cost function may be:

Σᵢ₌₁^{N}[ΔEᵢ]². Another exemplary cost function may be the maximum EPE of all segments, i.e.,

$${max}_{i = 1 , ... , N} \vert Δ {E}_{i} \vert$$

since the OPC goal may be set such that all EPE must be below a certain threshold.

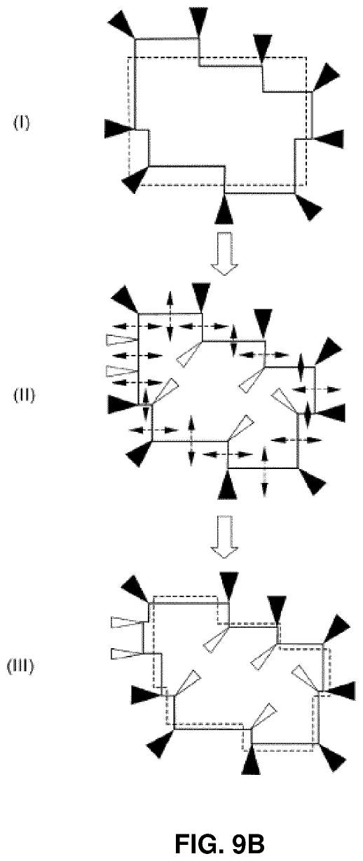

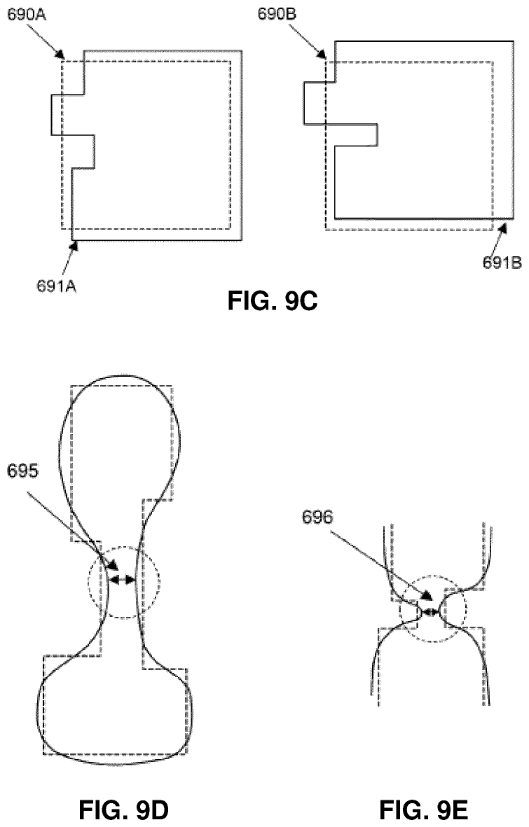

According to an embodiment, the edges of the main features and assist features may be split into a plurality of segments. During the process of finding preferred locations and shapes of the main features and assist features that satisfy a certain condition, such as a resist image produced matches a preferred resist image, each segment may be moved in a direction perpendicular thereto. According to an embodiment, the segments of the assist features may be moved without moving the segments of the main features or vice versa. As shown in the diagram in FIG. 9A, each segment can also be shifted in a direction parallel thereto as a result of movement of nearest neighboring segments connected thereto. However, the location of each segment in the direction perpendicular thereto is sufficient to dictate changes to the shapes and locations of the main features and assist features. For clarity, during this process, the location of each segment in the direction perpendicular thereto is denoted as CVₖ, k=1, . . . , M, wherein M is the total number of segments on the mask or a portion of the mask. For convenience, a vector CV is defined as

$$CV = ( \begin{matrix}{CV}_{1} \\ {CV}_{2} \\ ⋮ \\ ⋮ \\ {CV}_{M}\end{matrix} ) .$$

The location of each segment can also be represented as a change relative to the initial location of the segment. Namely, dCVₖ=CVₖ−CVₖ⁰, wherein CVₖ⁰ is the initial location of the k-th segment and dCVₖ is the change relative to the initial location CVₖ⁰. For convenience, vectors CV⁰ and dCV are defined as

$${CV}^{0} = ( \begin{matrix}{CV}_{1}^{0} \\ {CV}_{2}^{0} \\ ⋮ \\ ⋮ \\ {CV}_{M}^{0}\end{matrix} ) and dCV = ( \begin{matrix}{dCV}_{1} \\ {dCV}_{2} \\ ⋮ \\ ⋮ \\ {dCV}_{M}\end{matrix} ) . CV = {CV}^{0} + dCV .$$

A plurality of evaluation points can be placed on the mask. These evaluation points can be placed on the edges of the main features or off the edges of the main features such as at corners of the main features. Each segment can have any number (including zero) evaluation points thereon. EPE can be evaluated for each of these evaluation points and for a plurality of process conditions using a suitable model that simulate the resist image from the main and assist patterns, characteristics of the source, characteristics of the resist and other parameters of the lithography process. For convenience, a vector EPE is defined as EPE=(EPE₁(CV) EPE₂(CV) . . . EPE_{N}(CV)), wherein N is the total number of EPEs evaluated. Each of these EPEs is a function of the vector CV. Alternatively, each of these EPEs can be written as a function of the vector dCV as dCV differs from CV by a constant vector CV⁰. For example, if there are 4 evaluation points on a mask, and an EPE is evaluated for each of these 4 evaluation points at each of 2 process conditions, the vector EPE includes N=4×2=8 items. A Jacobian matrix J of the EPE vector with respect to the CV vector can be defined as

$$J = ( \begin{matrix}\frac{\partial {EPE}_{1}}{\partial {CV}_{1}} & \frac{\partial {EPE}_{1}}{\partial {CV}_{2}} & … & … & \frac{\partial {EPE}_{1}}{\partial {CV}_{M}} \\ \frac{\partial {EPE}_{2}}{\partial {CV}_{1}} & \frac{\partial {EPE}_{2}}{\partial {CV}_{2}} & … & … & \frac{\partial {EPE}_{2}}{\partial {CV}_{M}} \\ ⋮ & ⋮ & ⋱ & & ⋮ \\ ⋮ & ⋮ & & ⋱ & ⋮ \\ \frac{\partial {EPE}_{N}}{\partial {CV}_{1}} & \frac{\partial {EPE}_{N}}{\partial {CV}_{2}} & … & … & \frac{\partial {EPE}_{N}}{\partial {CV}_{M}}\end{matrix} ) ,$$

wherein J has N rows and M columns.

An exemplary cost function that measures how a lithographic metric such as the resist image is affected by changes to the main features and assist features characterized by CV or dCV can be defined as

$$CF = {\sum }_{i = 1}^{N} {EPE}_{i}^{2} = EPE \cdot {EPE}^{T} . \qquad ( Eq . 1 )$$

The lithographic metric can be edge placement error, critical dimension uniformity, dose variation, focus variation, process condition variation, mask error (MEEF), mask complexity, resist contour distance, worst defect size, best focus shift, and mask rule constraint.

In the example illustrated in FIG. 9B, panel (I) shows the feature in FIG. 9A after the segments of the feature are moved. Additional dissection points (open triangles in panels (II)) may be added to split some of the segments into additional segments.

Another example of the lithographic metric is a metric that measures difference between reconfiguration of a feature in one die and a corresponding feature in another die. This metric may be referred to as “geometry symmetry edges correction value” or GSECV. For example, FIG. 9C illustrates two square features 690A and 690B in two different dies; the two square features 690A and 690B correspond to each other. After reconfiguration, the two square features 690A and 690B become the features 691A and 691B, respectively GSECV can measure the difference between the features 691A and 691B. For example, GSECV may be defined as the difference between the areas of the features 691A and 691B. Of course, other definitions of GSECV are possible.

It should be appreciated that CF may have other suitable forms such as

$$CF = {\sum }_{i = 1}^{N} {EPE}_{i}^{4} , CF = {\sum }_{i = 1}^{N} \vert {EPE}_{i} \vert , CF = {max}_{i = 1 , ... , N} \vert {EPE}_{i} \vert$$

or a combination thereof.

The cost function can be minimized (or maximized for a cost function of certain form, such as CF=−Σᵢ₌₁^{N}EPEᵢ²) using any suitable method such as the Gauss-Newton algorithm, the interpolation method, the Levenberg-Marquardt algorithm, the gradient descent algorithm, simulated annealing, the interior point method, the genetic algorithm, solving polynomials, including higher-order polynomials of the CV or dCV.

According to an embodiment, the cost function of Eq. 1 can be minimized by the following iterative process. In the q-th iteration wherein CV take values of CV^{q}, the cost function of Eq. 1 is expanded into derivatives of the lithographic metric with respect to characteristics (e.g., CV) of the main features and the assist features, for example as shown in Eq. 2 below, wherein the cost function is expanded using the Jacobian matrix:

$$CF ( CV ) = CF ( {CV}^{q} ) + 2 \cdot EPE \cdot J \cdot dCV + {dCV}^{T} \cdot {J}^{T} \cdot J \cdot dCV + {\sum }_{j , k} {dCV}_{j} {dCV}_{k} {\sum }_{i} {EPE}_{i} \frac{{\partial }^{2} {EPE}_{i}}{\partial {CV}_{i} \partial {CV}_{k}} + O ( {‖ dCV ‖}^{3} ) . \qquad ( Eq . 2 )$$

The cost function can be approximated by omitting terms with derivatives above a predetermined order, such as the third order derivative term and above, i.e., the last term of Eq. 2. The approximated cost function can then be minimized by quadratic programming. Specifically, a value of dCV that yields a minimum of CF in the vicinity of CV^{q}, which is denoted as dCV^{q}, can be derived by omitting the last term of Eq. 2 and solving M linear equations of

$$\frac{\partial CF}{\partial {CV}_{k}} = 0.$$

Cv takes the value of (CV^{q}+dCV^{q}) in the (q+1)-th iteration: CV^{(q+1)}=(CV^{q}+dCV^{q}). This iteration continues until convergence (i.e. CF does not reduce any further) or a preset number of iterations is reached or a preset amount of time has passed. It should be appreciated that the cost function can be expanded in any other suitable manner. The Jacobian matrix can be calculated in every iterative step, or calculated in one iterative step and used in several succeeding iterative steps.

According to an embodiment, the cost function can be expanded in any other suitable ways. For example, the cost function can be expanded into Taylor series, Fourier series, wavelets, frames, sinc functions, Gaussian functions, etc.

In an embodiment, the cost function CF can include terms that measure relative alignment (i.e. relative position) of at least a pair of features selected from the main features and the assist features. The pair of features can include a main feature and an assist feature, two main features, or two assist features. Minimizing such a cost function can reduce the amount of relative movement between the pair of features. For example, the cost function can be

$$CF = {\sum }_{i = 1}^{N} {EPE}_{i}^{2} + w \cdot \sum {( {dCV}_{p} - {dCV}_{q} )}^{2} , \qquad ( Eq . 3 )$$

wherein the second summation includes all pairs of segments whose relative alignment is to be reduced, and weight w is a constant.

The cost function of Eq. 3 can be minimized by any suitable method including the iterative method above, i.e., iterative steps of expansion with respect to CV, omitting the third and higher derivatives, solving M linear equations of

$$\frac{\partial CF}{\partial {CV}_{k}} = 0.$$

In an embodiment, the cost function CF can include terms that measure the magnitudes of the changes to the main features and the assist features from the initial layout. For example, the cost function can be CF=Σᵢ₌₁^{N}EPEᵢ²+Σₖαₖ∥dCVₖ∥² (Eq. 4), wherein αₖ are weight constants. The cost function in Eq. 4 can be minimized by any suitable method including the iterative method above, i.e., iterative steps of expansion with respect to CV, omitting the third and higher derivatives, solving M linear equations of

$$\frac{\partial CF}{\partial {CV}_{k}} = 0.$$

In an embodiment, the lithographic process and the mask making process can be under various physical limitations. These limitations manifest as constraints in minimization or maximization of the cost function. In one example, dCV in an iterative step can be limited to be within a certain range. In one example, an EPE in an iterative step can be limited to be within a certain range. In one example, the resist image in an iterative step can be limited to be within a certain range. In another example, change of the distance between a pair of segments from an iterative step to the next can be limited to a certain range. The cost function under constraints can be minimized or maximized using any suitable constrained optimization methods.

One constraint is called “necking constraint.” The necking constraint is a lower bound to a width at any location of a resist image produced from a feature. For example, FIG. 9D illustrates a “neck” 695. The dotted line represents the feature; the curved solid line represents the resist image produced from this feature. If the neck 695 is narrower than the lower bound, the neck 695 is likely to break. Another constraint is called “bridging constraint.” The bridging constraint is a lower bound to a spacing between any edges of a resist image produced from one or more features. For example, FIG. 9E illustrates a “bridge” 696 between two features. The dotted line represents the features; the curved solid line represents the resist image produced from these features. If the bridge 696 is smaller than the lower bound, the edges are likely to merge.

In a mathematical form, such the cost function can include terms characteristic of these ranges. For example, if any function f_{z}(dCV) of dCV at an iterative step is to be limited within a range from b_{z} to t_{z} and it is desired to minimize |b_{z}| and |t_{z}|, the cost function can be CF=Σᵢ₌₁^{N}EPEᵢ²+Σ_{z}(β_{z}b_{z}²+γ_{z}t_{z}²) (Eq. 5), wherein β_{z} and γ_{z} are weight constants. Minimizing this cost function of Eq. 5 yields dCV that give minimal EPE, |b_{z}| and |t_{z}| at the same time. The function f_{z}(dCV) can be, for example, EPE, resist image, change of the distance between a pair of segments or any other suitable function of dCV.

In an embodiment, the cost function can include EPEs evaluated at process conditions farthest from a nominal condition. For example, the nominal condition is denoted as a pair of dose and focus values (d0, f0). In a production lithographic process wherein the largest expected deviation from the nominal condition is dd and df for dose and focus respectively (namely, the dose is expected not to go beyond d0±dd and the focus is expected not to go beyond f0±df), the cost function can include EPEs evaluated at one or more process conditions selected from (d0, f0), (d0+dd, f0+df), (d0+dd, f0−df), (d0−dd, f0+df), (d0−dd, f0−df), (do, f0+df), (d0, f0−df), (d0+dd, f0), (d0−dd, f0).

FIG. 10 is a block diagram that illustrates an exemplary computer system 100 configured to assist in implementing methods and flows disclosed herein in accordance with an embodiment of the present disclosure. Computer system 100 includes a bus 102 or other communication mechanism for communicating information, and a processor 104 (or multiple processors 104 and 105) coupled with bus 102 for processing information. Computer system 100 also includes a main memory 106, such as a random access memory (RAM) or other dynamic storage device, coupled to bus 102 for storing information and instructions to be executed by processor 104. Main memory 106 also may be used for storing temporary variables or other intermediate information during execution of instructions to be executed by processor 104. Computer system 100 further includes a read only memory (ROM) 108 or other static storage device coupled to bus 102 for storing static information and instructions for processor 104. A storage device 110, such as a magnetic disk or optical disk, is provided and coupled to bus 102 for storing information and instructions.

Computer system 100 may be coupled via bus 102 to a display 112, such as a cathode ray tube (CRT) or flat panel or touch panel display for displaying information to a computer user. An input device 114, including alphanumeric and other keys, is coupled to bus 102 for communicating information and command selections to processor 104. Another type of user input device is cursor control 116, such as a mouse, a trackball, or cursor direction keys for communicating direction information and command selections to processor 104 and for controlling cursor movement on display 112. This input device typically has two degrees of freedom in two axes, a first axis (e.g., x) and a second axis (e.g., y), that allows the device to specify positions in a plane. A touch panel (screen) display may also be used as an input device.

According to one embodiment, portions of the process may be performed by computer system 100 in response to processor 104 executing one or more sequences of one or more instructions contained in main memory 106. Such instructions may be read into main memory 106 from another computer-readable medium, such as storage device 110. Execution of the sequences of instructions contained in main memory 106 causes processor 104 to perform the process steps described herein. One or more processors in a multi-processing arrangement may also be employed to execute the sequences of instructions contained in main memory 106. In an alternative embodiment, hard-wired circuitry may be used in place of or in combination with software instructions. Thus, the description herein is not limited to any specific combination of hardware circuitry and software.

The term “computer-readable medium” as used herein refers to any medium that participates in providing instructions to processor 104 for execution. Such a medium may take many forms, including but not limited to, non-volatile media, volatile media, and transmission media. Non-volatile media include, for example, optical or magnetic disks, such as storage device 110. Volatile media include dynamic memory, such as main memory 106. Transmission media include coaxial cables, copper wire and fiber optics, including the wires that comprise bus 102. Transmission media can also take the form of acoustic or light waves, such as those generated during radio frequency (RF) and infrared (IR) data communications. Common forms of computer-readable media include, for example, a floppy disk, a flexible disk, hard disk, magnetic tape, any other magnetic medium, a CD-ROM, DVD, any other optical medium, punch cards, paper tape, any other physical medium with patterns of holes, a RAM, a PROM, and EPROM, a FLASH-EPROM, any other memory chip or cartridge, a carrier wave as described hereinafter, or any other medium from which a computer can read.

Various forms of computer readable media may be involved in carrying one or more sequences of one or more instructions to processor 104 for execution. For example, the instructions may initially be borne on a magnetic disk of a remote computer. The remote computer can load the instructions into its dynamic memory and send the instructions over a telephone line using a modem. A modem local to computer system 100 can receive the data on the telephone line and use an infrared transmitter to convert the data to an infrared signal. An infrared detector coupled to bus 102 can receive the data carried in the infrared signal and place the data on bus 102. Bus 102 carries the data to main memory 106, from which processor 104 retrieves and executes the instructions. The instructions received by main memory 106 may optionally be stored on storage device 110 either before or after execution by processor 104.

Computer system 100 also desirably includes a communication interface 118 coupled to bus 102. Communication interface 118 provides a two-way data communication coupling to a network link 120 that is connected to a local network 122. For example, communication interface 118 may be an integrated services digital network (ISDN) card or a modem to provide a data communication connection to a corresponding type of telephone line. As another example, communication interface 118 may be a local area network (LAN) card to provide a data communication connection to a compatible LAN. Wireless links may also be implemented. In any such implementation, communication interface 118 sends and receives electrical, electromagnetic or optical signals that carry digital data streams representing various types of information.

Network link 120 typically provides data communication through one or more networks to other data devices. For example, network link 120 may provide a connection through local network 122 to a host computer 124 or to data equipment operated by an Internet Service Provider (ISP) 126. ISP 126 in turn provides data communication services through the worldwide packet data communication network, now commonly referred to as the “Internet” 128. Local network 122 and Internet 128 both use electrical, electromagnetic or optical signals that carry digital data streams. The signals through the various networks and the signals on network link 120 and through communication interface 118, which carry the digital data to and from computer system 100, are example forms of carrier waves transporting the information.

Computer system 100 can send messages and receive data, including program code, through the network(s), network link 120, and communication interface 118. In the Internet example, a server 130 might transmit a requested code for an application program through Internet 128, ISP 126, local network 122 and communication interface 118. One such downloaded application may provide for the illumination optimization of the embodiment, for example. The received code may be executed by processor 104 as it is received, and/or stored in storage device 110, or other non-volatile storage for later execution. In this manner, computer system 100 may obtain application code in the form of a carrier wave.

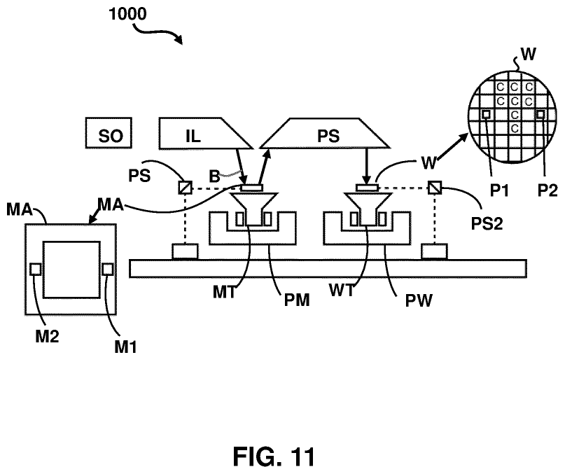

FIG. 11 depicts another exemplary lithographic projection apparatus 1000 in accordance with an embodiment of the present disclosure. Apparatus 1000 includes:
a source collector module SO to provide radiation.
an illumination system (illuminator) IL configured to condition a radiation beam B (e.g. EUV radiation) from the source collector module SO.
a support structure (e.g. a mask table) MT constructed to support a patterning device (e.g. a mask or a reticle) MA and connected to a first positioner PM configured to accurately position the patterning device;
a substrate table (e.g. a wafer table) WT constructed to hold a substrate (e.g. a resist coated wafer) W and connected to a second positioner PW configured to accurately position the substrate; and
a projection system (e.g. a reflective projection system) PS configured to project a pattern imparted to the radiation beam B by patterning device MA onto a target portion C (e.g. comprising one or more dies) of the substrate W.

As here depicted, the apparatus 1000 is of a reflective type (e.g. employing a reflective mask). It is to be noted that because most materials are absorptive within the EUV wavelength range, the patterning device may have multilayer reflectors comprising, for example, a multi-layer stack of molybdenum and silicon. In one example, the multi-stack reflector has a 40 layer pairs of Molybdenum and Silicon where the thickness of each layer is a quarter wavelength. Even smaller wavelengths may be produced with X-ray lithography. Since most material is absorptive at EUV and x-ray wavelengths, a thin piece of patterned absorbing material on the patterning device topography (e.g., a TaN absorber on top of the multi-layer reflector) defines where features would print (positive resist) or not print (negative resist).

Referring to FIG. 11, the illuminator IL receives an extreme ultra violet radiation beam from the source collector module SO. Methods to produce EUV radiation include, but are not necessarily limited to, converting a material into a plasma state that has at least one element, e.g., xenon, lithium or tin, with one or more emission lines in the EUV range. In one such method, often termed laser produced plasma (“LPP”) the plasma can be produced by irradiating a fuel, such as a droplet, stream or cluster of material having the line-emitting element, with a laser beam. The source collector module SO may be part of an EUV radiation system including a laser, not shown in FIG. 11, for providing the laser beam exciting the fuel. The resulting plasma emits output radiation, e.g., EUV radiation, which is collected using a radiation collector, disposed in the source collector module. The laser and the source collector module may be separate entities, for example when a CO2 laser is used to provide the laser beam for fuel excitation.

In such cases, the laser is not considered to form part of the lithographic apparatus and the radiation beam is passed from the laser to the source collector module with the aid of a beam delivery system comprising, for example, suitable directing mirrors and/or a beam expander. In other cases the radiation source may be an integral part of the source collector module, for example when the radiation source is a discharge produced plasma EUV generator, often termed as a DPP radiation source.

The illuminator IL may comprise an adjuster for adjusting the angular intensity distribution of the radiation beam. Generally, at least the outer and/or inner radial extent (commonly referred to as σ-outer and σ-inner, respectively) of the intensity distribution in a pupil plane of the illuminator can be adjusted. In addition, the illuminator IL may comprise various other components, such as facetted field and pupil mirror devices. The illuminator may be used to condition the radiation beam, to have a desired uniformity and intensity distribution in its cross section.

The radiation beam B is incident on the patterning device (e.g., mask) MA, which is held on the support structure (e.g., mask table) MT, and is patterned by the patterning device. After being reflected from the patterning device (e.g. mask) MA, the radiation beam B passes through the projection system PS, which focuses the beam onto a target portion C of the substrate W. With the aid of the second positioner PW and position sensor PS2 (e.g. an interferometric device, linear encoder or capacitive sensor), the substrate table WT can be moved accurately, e.g. so as to position different target portions C in the path of the radiation beam B. Similarly, the first positioner PM and another position sensor PSI can be used to accurately position the patterning device (e.g. mask) MA with respect to the path of the radiation beam B. Patterning device (e.g. mask) MA and substrate W may be aligned using patterning device alignment marks M1, M2 and substrate alignment marks P1, P2.

The depicted apparatus 1000 could be used in at least one of the following modes:

1. In step mode, the support structure (e.g. mask table) MT and the substrate table WT are kept essentially stationary, while an entire pattern imparted to the radiation beam is projected onto a target portion C at one time (i.e. a single static exposure). The substrate table WT is then shifted in the X and/or Y direction so that a different target portion C can be exposed.

2. In scan mode, the support structure (e.g. mask table) MT and the substrate table WT are scanned synchronously while a pattern imparted to the radiation beam is projected onto a target portion C (i.e. a single dynamic exposure). The velocity and direction of the substrate table WT relative to the support structure (e.g. mask table) MT may be determined by the (de-)magnification and image reversal characteristics of the projection system PS.

3. In another mode, the support structure (e.g. mask table) MT is kept essentially stationary holding a programmable patterning device, and the substrate table WT is moved or scanned while a pattern imparted to the radiation beam is projected onto a target portion C. In this mode, generally a pulsed radiation source is employed and the programmable patterning device is updated as required after each movement of the substrate table WT or in between successive radiation pulses during a scan. This mode of operation can be readily applied to maskless lithography that utilizes programmable patterning device, such as a programmable mirror array of a type as referred to above.

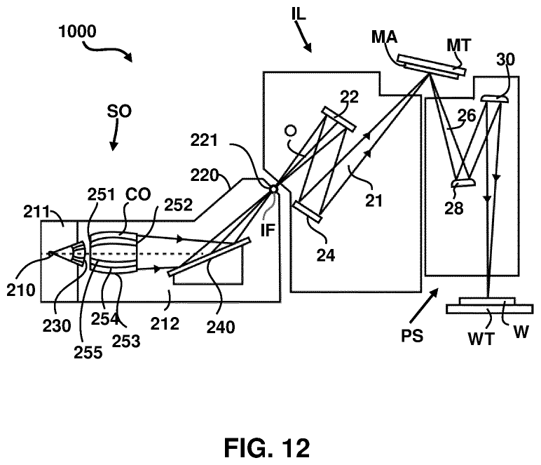

FIG. 12 shows the apparatus 1000 in more detail, including the source collector module SO, the illumination system IL, and the projection system PS. The source collector module SO is constructed and arranged such that a vacuum environment can be maintained in an enclosing structure 220 of the source collector module SO. An EUV radiation emitting plasma 210 may be formed by a discharge produced plasma radiation source. EUV radiation may be produced by a gas or vapor, for example Xe gas, Li vapor or Sn vapor in which the very hot plasma 210 is created to emit radiation in the EUV range of the electromagnetic spectrum. The very hot plasma 210 is created by, for example, an electrical discharge causing an at least partially ionized plasma. Partial pressures of, for example, 10 Pa of Xe, Li, Sn vapor or any other suitable gas or vapor may be required for efficient generation of the radiation. In an embodiment, a plasma of excited tin (Sn) is provided to produce EUV radiation.

The radiation emitted by the hot plasma 210 is passed from a source chamber 211 into a collector chamber 212 via an optional gas barrier or contaminant trap 230 (in some cases also referred to as contaminant barrier or foil trap) which is positioned in or behind an opening in source chamber 211. The contaminant trap 230 may include a channel structure. Contamination trap 230 may also include a gas barrier or a combination of a gas barrier and a channel structure. The contaminant trap or contaminant barrier 230 further indicated herein at least includes a channel structure, as known in the art.

The collector chamber 211 may include a radiation collector CO which may be a so-called grazing incidence collector. Radiation collector CO has an upstream radiation collector side 251 and a downstream radiation collector side 252. Radiation that traverses collector CO can be reflected off a grating spectral filter 240 to be focused in a virtual source point IF along the optical axis indicated by the dot-dashed line ‘O’. The virtual source point IF is commonly referred to as the intermediate focus, and the source collector module is arranged such that the intermediate focus IF is located at or near an opening 221 in the enclosing structure 220. The virtual source point IF is an image of the radiation emitting plasma 210.

Subsequently the radiation traverses the illumination system IL, which may include a facetted field mirror device 22 and a facetted pupil mirror device 24 arranged to provide a desired angular distribution of the radiation beam 21, at the patterning device MA, as well as a desired uniformity of radiation intensity at the patterning device MA. Upon reflection of the beam of radiation 21 at the patterning device MA, held by the support structure MT, a patterned beam 26 is formed and the patterned beam 26 is imaged by the projection system PS via reflective elements 28, 30 onto a substrate W held by the substrate table WT.

More elements than shown may generally be present in illumination optics unit IL and projection system PS. The grating spectral filter 240 may optionally be present, depending upon the type of lithographic apparatus. Further, there may be more mirrors present than those shown in the Figures, for example there may be 1-6 additional reflective elements present in the projection system PS than shown in FIG. 12.

Collector optic CO, as illustrated in FIG. 12, is depicted as a nested collector with grazing incidence reflectors 253, 254 and 255, just as an example of a collector (or collector mirror). The grazing incidence reflectors 253, 254 and 255 are disposed axially symmetric around the optical axis O and a collector optic CO of this type is desirably used in combination with a discharge produced plasma radiation source.

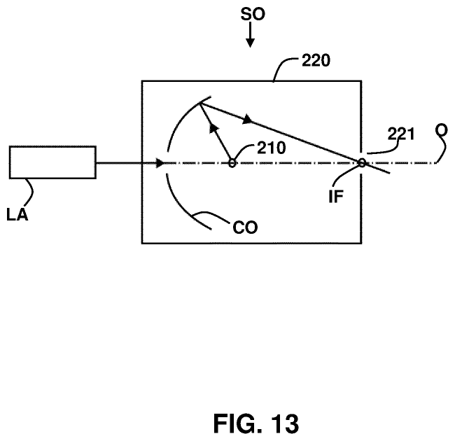

Alternatively, the source collector module SO may be part of an LPP radiation system as shown in FIG. 13. A laser LAS is arranged to deposit laser energy into a fuel, such as xenon (Xe), tin (Sn) or lithium (Li), creating the highly ionized plasma 210 with electron temperatures of several 10's of eV. The energetic radiation generated during de-excitation and recombination of these ions is emitted from the plasma, collected by a near normal incidence collector optic CO and focused onto the opening 221 in the enclosing structure 220.

The concepts disclosed herein may simulate or mathematically model any generic imaging system for imaging sub wavelength features, and may be especially useful with emerging imaging technologies capable of producing wavelengths of an increasingly smaller size. Emerging technologies already in use include EUV (extreme ultra violet) lithography that is capable of producing a 193 nm wavelength with the use of an ArF laser, and even a 157 nm wavelength with the use of a Fluorine laser. Moreover, EUV lithography is capable of producing wavelengths within a range of 20-5 nm by using a synchrotron or by hitting a material (either solid or a plasma) with high energy electrons in order to produce photons within this range.

While the concepts disclosed herein may be used for imaging on a substrate such as a silicon wafer, it shall be understood that the disclosed concepts may be used with any type of lithographic imaging systems, e.g., those used for imaging on substrates other than silicon wafers.

Although specific reference may be made in this text to the use of embodiments in the manufacture of ICs, it should be understood that the embodiments herein may have many other possible applications. For example, it may be employed in the manufacture of integrated optical systems, guidance and detection patterns for magnetic domain memories, liquid-crystal displays (LCDs), thin film magnetic heads, micromechanical systems (MEMs), etc. The skilled artisan will appreciate that, in the context of such alternative applications, any use of the terms “reticle”, “wafer” or “die” herein may be considered as synonymous or interchangeable with the more general terms “patterning device”, “substrate” or “target portion”, respectively. The substrate referred to herein may be processed, before or after exposure, in for example a track (a tool that typically applies a layer of resist to a substrate and develops the exposed resist) or a metrology or inspection tool. Where applicable, the disclosure herein may be applied to such and other substrate processing tools. Further, the substrate may be processed more than once, for example in order to create, for example, a multi-layer IC, so that the term substrate used herein may also refer to a substrate that already contains multiple processed layers.

In the present document, the terms “radiation” and “beam” as used herein encompass all types of electromagnetic radiation, including ultraviolet radiation (e.g. with a wavelength of about 365, about 248, about 193, about 157 or about 126 nm) and extreme ultra-violet (EUV) radiation (e.g. having a wavelength in the range of 5-20 nm), as well as particle beams, such as ion beams or electron beams.

The terms “optimizing” and “optimization” as used herein refers to or means adjusting a patterning apparatus (e.g., a lithography apparatus), a patterning process, etc. such that results and/or processes have more desirable characteristics, such as higher accuracy of projection of a design pattern on a substrate, a larger process window, etc. Thus, the term “optimizing” and “optimization” as used herein refers to or means a process that identifies one or more values for one or more parameters that provide an improvement, e.g. a local optimum, in at least one relevant metric, compared to an initial set of one or more values for those one or more parameters. “Optimum” and other related terms should be construed accordingly. In an embodiment, optimization steps can be applied iteratively to provide further improvements in one or more metrics.

Aspects of the invention can be implemented in any convenient form. For example, an embodiment may be implemented by one or more appropriate computer programs which may be carried on an appropriate carrier medium which may be a tangible carrier medium (e.g. a disk) or an intangible carrier medium (e.g. a communications signal). Embodiments of the invention may be implemented using suitable apparatus which may specifically take the form of a programmable computer running a computer program arranged to implement a method as described herein. Thus, embodiments of the disclosure may be implemented in hardware, firmware, software, or any combination thereof. Embodiments of the disclosure may also be implemented as instructions stored on a machine-readable medium, which may be read and executed by one or more processors. A machine-readable medium may include any mechanism for storing or transmitting information in a form readable by a machine (e.g., a computing device). For example, a machine-readable medium may include read only memory (ROM); random access memory (RAM); magnetic disk storage media; optical storage media; flash memory devices; electrical, optical, acoustical or other forms of propagated signals (e.g. carrier waves, infrared signals, digital signals, etc.), and others. Further, firmware, software, routines, instructions may be described herein as performing certain actions. However, it should be appreciated that such descriptions are merely for convenience and that such actions in fact result from computing devices, processors, controllers, or other devices executing the firmware, software, routines, instructions, etc.

Embodiments of the present disclosure can be further described by the following clauses.

1. A non-transitory computer-readable medium having instructions recorded thereon, the instructions, when executed by one or more processors, implementing a method for generating a mask pattern for a lithographic process, the method comprising:
accessing a first segmented mask pattern comprising a plurality of segmented features of a first mask pattern;
generating a smoothed representation of the first segmented mask pattern by applying a first smoothing function;
adjusting the first segmented mask pattern by a set of changes to one or more of the plurality of segmented features;
generating, using the first smoothing function, a smoothed representation of the adjusted segmented mask pattern;
evaluating the smoothed representation by simulating a patterning process using the smoothed representation of the adjusted segmented mask pattern;
obtaining, based on the adjusted segmented mask pattern, a resultant segmented mask pattern; and
generating, based on a second smoothing function and the resultant segmented mask pattern, a mask pattern having smoothed features.

2. The medium of clause 1, wherein the evaluating of the smoothed representation comprising: determining whether the simulation results satisfy a termination condition associated with the patterning process, wherein the simulation results are generated when the set of changes is made to the one or more of the plurality of segmented features.

3. The medium of clause 2, wherein the obtaining of the resultant segmented mask pattern is an iterative process, each iteration comprising simulating the patterning process that includes process models configured to apply the smoothing function to the segmented mask pattern.

4. The medium of clause 3, wherein, each iteration of the obtaining of the resultant segmented mask pattern comprises:
(a) adjusting the first segmented mask pattern with a first change of the set of changes of the more or more of the plurality of segmented features;
(b) generating, using the first smoothing function, the smoothed representation of the adjusted segmented mask pattern;
(c) simulating the patterning process using the smoothed representation of the adjusted segmented mask pattern;
(c) globally evaluating the simulation results based on the adjusted segmented pattern;
(d) determining whether the simulation results satisfy the termination condition; and

(e) responsive to the termination condition not being satisfied, adjusting based on the evaluation, the first segmented mask pattern with a second change of the set of changes of the one or more of the plurality of segmented features, and repeating steps (b)-(e).

5. The medium of any of clauses 1-4, wherein the evaluating comprises:
evaluating a cost function that measures how a lithographic metric is affected by the set of changes to the plurality of segmented features for a plurality of lithographic process conditions, wherein the cost function comprises a function of the smoothed representation.

6. The medium of clause 5, wherein the evaluating comprises:
calculating a Jacobian matrix, wherein the Jacobian matrix comprises a set of derivatives of a function of the smoothed representation with respect to the plurality of segments of the first segmented mask pattern.

7. The medium of clause 6, wherein the evaluating comprises:
evaluating the cost function using the Jacobian matrix.

8. The medium of any of clauses 5-7, wherein the simulating of the patterning process comprises executing a multi-variable solver implementing the cost function and the Jacobian matrix to generate a free form mask pattern.

9. The medium of any of clause 8, wherein the cost function is a function of at least one of:
relative alignment of at least a pair of the plurality of segmented features,
magnitudes of the changes to the plurality of segmented features, and
characteristics of a resist image or an aerial image.

10. The medium of any of clauses 5-9, wherein the cost function is a function of a probability of a function of the features and a process window defined by the plurality of lithographic process conditions having a value outside a permitted range.

11. The medium of any of clauses 5-10, wherein the plurality of lithographic process conditions comprises a plurality of different focus and dose values.

12. The medium of any of clauses 5-11, wherein the termination condition includes one or more of: minimization of the cost function; maximization of the cost function; reaching a preset number of iterations; reaching a value of the cost function equal to or beyond a preset threshold value; reaching a predefined computation time; and reaching a value of the cost function within an acceptable error limit.

13. The medium of any of clauses 5-12, wherein the cost function is a function of one or more of the following lithographic metrics: edge placement error, critical dimension uniformity, dose variation, focus variation, process condition variation, mask error (MEEF), mask complexity, resist contour distance, worst defect size, best focus shift, and mask rule constraint.

14. The medium of any of clauses 1-13, wherein the adjusting comprises:
changing to one or more main features of the first segmented mask pattern;
changing to one or more assist features of the first segmented mask pattern; or
simultaneously changing both the main features and the assist features of the first segmented mask pattern.

15. The medium of clause 14, wherein the assist features include one or more of sub-resolution assist features (SRAF) and sub-resolution inverse features (SRIF).

16. The medium of any of clauses 1-15, wherein the changes include movement of segments of boundaries of the features.

17. The medium of clause 16, wherein the changes include changes of shapes of the features.

18. The medium of clause 17, wherein the changes include changes of locations of the features.

19. The medium of any of clauses 1-18, wherein the adjusting is performed under constraints dictating a range of at least some of the changes to the plurality of segmented features.

20. The medium of any of clauses 1-19, further comprising:
placing evaluation points on the segments of the plurality of features, wherein determining includes evaluating the cost function over all of the evaluation points.

21. The medium of any of clauses 1-20, wherein the first mask pattern comprises a plurality of curved features, and wherein the plurality of segmented features of the first segmented mask pattern correspond to the plurality of curved features.

22. The medium of clause 1, accessing the first segmented mask pattern comprises:
accessing the first mask pattern comprising a plurality of features; and
converting the first mask pattern into the first segmented mask pattern by segmenting a feature of the plurality of features into a plurality of segments, each segment being a line.

23. The medium of clause 22, the converting comprises:
approximating the feature of the first mask pattern into the plurality of segments, each segment being oriented at a desired angle with respect to an adjacent segment.

24. The medium of clause 23, the converting comprises:
dissecting the feature of the first mask pattern into the plurality of segments to generate staircased features, wherein each segment is oriented at 90° angle with respect to an adjacent segment.

25. The medium of any of clauses 1-24, wherein the first and the second smoothing functions are Gaussian functions.

26. The medium of any of clauses 1-25, wherein the first smoothing function and the second smoothing function are the same.

27. A method for generating a mask pattern for a lithographic process, the method comprising: accessing a first segmented mask pattern comprising a plurality of segmented features of a first mask pattern;
generating a smoothed representation of the first segmented mask pattern by applying a first smoothing function;
adjusting the first segmented mask pattern by with a set of changes to one or more of the plurality of segmented features;
generating, using the first smoothing function, a smoothed representation of the adjusted segmented mask pattern;
evaluating the smoothed representation by simulating a patterning process using the smoothed representation of the adjusted segmented mask pattern;
obtaining, based on the adjusted segmented mask pattern, a resultant segmented mask pattern; and
generating, based on a second smoothing function and the resultant segmented mask pattern, a mask pattern having smoothed features.

28. The method of clause 27, wherein the evaluating of the smoothed representation comprising:
determining whether the simulation results satisfy a termination condition associated with the patterning process, wherein the simulation results are generated when the set of changes is made to the one or more of the plurality of segmented features.

29. The method of clause 28, wherein the obtaining of the resultant segmented mask pattern is an iterative process, each iteration comprising simulating the patterning process that includes process models configured to apply the smoothing function to the segmented mask pattern.

30. The method of clause 29, wherein, each iteration of the obtaining of the resultant segmented mask pattern comprises:
(a) adjusting the first segmented mask pattern with a first change of the set of changes of the more or more of the plurality of segmented features;
(b) generating, using the first smoothing function, the smoothed representation of the adjusted segmented mask pattern;
(c) globally evaluating the simulation results based on the adjusted segmented pattern;
(d) determining whether the simulation results satisfy the termination condition; and
(e) responsive to the termination condition not being satisfied, adjusting, based on the evaluation, the first segmented mask pattern with a second change of the set of changes of the one or more of the plurality of segmented features, and repeating steps (b)-(e).

31. The method of any of clauses 27-310 wherein the evaluating comprises:
evaluating a cost function that measures how a lithographic metric is affected by the set of changes to the plurality of segmented features for a plurality of lithographic process conditions, wherein the cost function comprises a function of the smoothed representation.

32. The method of clause 31, wherein the evaluating comprises:
calculating a Jacobian matrix, wherein the Jacobian matrix comprises a set of derivatives of a function of the smoothed representation with respect to the plurality of segments of the first segmented mask pattern.

33. The method of clause 32, wherein the evaluating comprises:
evaluating the cost function using the Jacobian matrix.

34. The method of any of clauses 32-33, wherein the simulating of the patterning process comprises executing a multi-variable solver implementing the cost function and the Jacobian matrix to generate a free form mask pattern.

35. The method of any of clauses 31-34, wherein the cost function is a function of at least one of: relative alignment of at least a pair of the plurality of segmented features, magnitudes of the changes to the plurality of segmented features, and characteristics of a resist image or an aerial image.

36. The method of any of clauses 31-35, wherein the cost function is a function of a probability of a function of the features and a process window defined by the plurality of lithographic process conditions having a value outside a permitted range.

37. The method of any of clauses 31-36, wherein the plurality of lithographic process conditions comprises a plurality of different focus and dose values.

38. The method of any of clauses 31-37, wherein the termination condition includes one or more of: minimization of the cost function; maximization of the cost function; reaching a preset number of iterations; reaching a value of the cost function equal to or beyond a preset threshold value; reaching a predefined computation time; and reaching a value of the cost function within an acceptable error limit.

39. The method of any of clauses 31-38, wherein the cost function is a function of one or more of the following lithographic metrics: edge placement error, critical dimension uniformity, dose variation, focus variation, process condition variation, mask error (MEEF), mask complexity, resist contour distance, worst defect size, best focus shift, and mask rule constraint.

40. The method of any of clauses 27-39, wherein the adjusting comprises:
changing to one or more main features of the first segmented mask pattern;
changing to one or more assist features of the first segmented mask pattern; or
simultaneously changing both the main features and the assist features of the first segmented mask pattern.

41. The method of clause 40, wherein the assist features include one or more of sub-resolution assist features (SRAF) and sub-resolution inverse features (SRIF).

42. The method of any of clauses 27-41, wherein the changes include movement of segments of boundaries of the features.

43. The method of clause 42, wherein the changes include changes of shapes of the features.

44. The method of clause 43, wherein the changes include changes of locations of the features.

45. The method of any of clauses 27-44, wherein the adjusting is performed under constraints dictating a range of at least some of the changes to the plurality of segmented features.

46. The method of any of clauses 27-45, further comprising:
placing evaluation points on the segments of the plurality of features, wherein determining includes evaluating the cost function over all of the evaluation points.

47. The method of any of clauses 27-46, wherein the first mask pattern comprises a plurality of curved features, and wherein the plurality of segmented features of the first segmented mask pattern correspond to the plurality of curved features.

48. The method of clause 27, accessing the first segmented mask pattern comprises:
accessing the first mask pattern comprising a plurality of features; and
converting the first mask pattern into the first segmented mask pattern by segmenting a feature of the plurality of features into a plurality of segments, each segment being a line.

49. The method of clause 48, the converting comprises:
approximating the feature of the first mask pattern into the plurality of segments, each segment being oriented at a desired angle with respect to an adjacent segment.

50. The method of clause 48, the converting comprises:
dissecting the feature of the first mask pattern into the plurality of segments to generate staircased features, wherein each segment is oriented at 90° angle with respect to an adjacent segment.

51. The method of any of clauses 27-50, wherein the first and the second smoothing functions are Gaussian functions.

52. The method of any of clauses 27-47, wherein the first smoothing function and the second smoothing function are the same.

In block diagrams, illustrated components are depicted as discrete functional blocks, but embodiments are not limited to systems in which the functionality described herein is organized as illustrated. The functionality provided by each of the components may be provided by software or hardware modules that are differently organized than is presently depicted, for example such software or hardware may be intermingled, conjoined, replicated, broken up, distributed (e.g. within a data center or geographically), or otherwise differently organized. The functionality described herein may be provided by one or more processors of one or more computers executing code stored on a tangible, non-transitory, machine readable medium. In some cases, third party content delivery networks may host some or all of the information conveyed over networks, in which case, to the extent information (e.g., content) is said to be supplied or otherwise provided, the information may be provided by sending instructions to retrieve that information from a content delivery network.

Unless specifically stated otherwise, as apparent from the discussion, it is appreciated that throughout this specification discussions utilizing terms such as “processing,” “computing,” “calculating,” “determining” or the like refer to actions or processes of a specific apparatus, such as a special purpose computer or a similar special purpose electronic processing/computing device.

The reader should appreciate that the present application describes several inventions. Rather than separating those inventions into multiple isolated patent applications, these inventions have been grouped into a single document because their related subject matter lends itself to economies in the application process. But the distinct advantages and aspects of such inventions should not be conflated. In some cases, embodiments address all of the deficiencies noted herein, but it should be understood that the inventions are independently useful, and some embodiments address only a subset of such problems or offer other, unmentioned benefits that will be apparent to those of skill in the art reviewing the present disclosure. Due to costs constraints, some inventions disclosed herein may not be presently claimed and may be claimed in later filings, such as continuation applications or by amending the present claims. Similarly, due to space constraints, neither the Abstract nor the Summary sections of the present document should be taken as containing a comprehensive listing of all such inventions or all aspects of such inventions.

It should be understood that the description and the drawings are not intended to limit the present disclosure to the particular form disclosed, but to the contrary, the intention is to cover all modifications, equivalents, and alternatives falling within the spirit and scope of the inventions as defined by the appended claims.

Modifications and alternative embodiments of various aspects of the inventions will be apparent to those skilled in the art in view of this description. Accordingly, this description and the drawings are to be construed as illustrative only and are for the purpose of teaching those skilled in the art the general manner of carrying out the inventions. It is to be understood that the forms of the inventions shown and described herein are to be taken as examples of embodiments. Elements and materials may be substituted for those illustrated and described herein, parts and processes may be reversed or omitted, certain features may be utilized independently, and embodiments or features of embodiments may be combined, all as would be apparent to one skilled in the art after having the benefit of this description. Changes may be made in the elements described herein without departing from the spirit and scope of the invention as described in the following claims. Headings used herein are for organizational purposes only and are not meant to be used to limit the scope of the description.

As used throughout this application, the word “may” is used in a permissive sense (i.e., meaning having the potential to), rather than the mandatory sense (i.e., meaning must). The words “include”, “including”, and “includes” and the like mean including, but not limited to. As used throughout this application, the singular forms “a,” “an,” and “the” include plural referents unless the content explicitly indicates otherwise. Thus, for example, reference to “an” element or “a” element includes a combination of two or more elements, notwithstanding use of other terms and phrases for one or more elements, such as “one or more.” The term “or” is, unless indicated otherwise, non-exclusive, i.e., encompassing both “and” and “or.” Terms describing conditional relationships, e.g., “in response to X, Y,” “upon X, Y,”, “if X, Y,” “when X, Y,” and the like, encompass causal relationships in which the antecedent is a necessary causal condition, the antecedent is a sufficient causal condition, or the antecedent is a contributory causal condition of the consequent, e.g., “state X occurs upon condition Y obtaining” is generic to “X occurs solely upon Y” and “X occurs upon Y and Z.” Such conditional relationships are not limited to consequences that instantly follow the antecedent obtaining, as some consequences may be delayed, and in conditional statements, antecedents are connected to their consequents, e.g., the antecedent is relevant to the likelihood of the consequent occurring. Statements in which a plurality of attributes or functions are mapped to a plurality of objects (e.g., one or more processors performing steps A, B, C, and D) encompasses both all such attributes or functions being mapped to all such objects and subsets of the attributes or functions being mapped to subsets of the attributes or functions (e.g., both all processors each performing steps A-D, and a case in which processor 1 performs step A, processor 2 performs step B and part of step C, and processor 3 performs part of step C and step D), unless otherwise indicated. Further, unless otherwise indicated, statements that one value or action is “based on” another condition or value encompass both instances in which the condition or value is the sole factor and instances in which the condition or value is one factor among a plurality of factors. Unless otherwise indicated, statements that “each” instance of some collection have some property should not be read to exclude cases where some otherwise identical or similar members of a larger collection do not have the property, i.e., each does not necessarily mean each and every. References to selection from a range includes the end points of the range.

In the above description, any processes, descriptions or blocks in flowcharts should be understood as representing modules, segments or portions of code which include one or more executable instructions for implementing specific logical functions or steps in the process, and alternate implementations are included within the scope of the exemplary embodiments of the present advancements in which functions can be executed out of order from that shown or discussed, including substantially concurrently or in reverse order, depending upon the functionality involved, as would be understood by those skilled in the art.

To the extent certain U.S. patents, U.S. patent applications, PCT patent applications or publications, or other materials (e.g., articles) have been incorporated by reference, the text of such U.S. patents, U.S. patent applications, and other materials is only incorporated by reference to the extent that no conflict exists between such material and the statements and drawings set forth herein. In the event of such conflict, any such conflicting text in such incorporated by reference U.S. patents, U.S. patent applications, and other materials is specifically not incorporated by reference herein.

While certain embodiments have been described, these embodiments have been presented by way of example only, and are not intended to limit the scope of the present disclosures. Indeed, the novel methods, apparatuses and systems described herein can be embodied in a variety of other forms; furthermore, various omissions, substitutions and changes in the form of the methods, apparatuses and systems described herein can be made without departing from the spirit of the present disclosures. The accompanying claims and their equivalents are intended to cover such forms or modifications as would fall within the scope and spirit of the present disclosures.

1. A method of determining a mask pattern for a lithographic process, the method comprising:
accessing a first segmented mask pattern comprising a plurality of segmented features of a first mask pattern;
generating a smoothed representation of the first segmented mask pattern by applying a first smoothing function;
adjusting the first segmented mask pattern by a set of changes to one or more of the plurality of segmented features;
generating, using the first smoothing function, a smoothed representation of the adjusted segmented mask pattern;
evaluating the smoothed representation by performing a computer simulation of a patterning process using the smoothed representation of the adjusted segmented mask pattern;
obtaining, based on the adjusted segmented mask pattern, a resultant segmented mask pattern; and
generating, based on a second smoothing function and the resultant segmented mask pattern, a mask pattern having smoothed features.

2. The method of claim 1, wherein the obtaining of the resultant segmented mask pattern is an iterative process, each iteration comprising simulating the patterning process that includes one or more process models configured to apply the smoothing function to the segmented mask pattern.

3. (canceled)

4. The method of claim 1, wherein the evaluating comprises evaluating a cost function comprising a lithographic metric correlated to the set of changes to one or more of the plurality of segmented features for a plurality of lithographic process conditions, wherein the cost function comprises a function of the smoothed representation.

5.-9. (canceled)

10. The method of claim 1, wherein the first mask pattern comprises a plurality of curved features, and wherein the plurality of segmented features of the first segmented mask pattern correspond to the plurality of curved features.

11. The method of claim 1, wherein the accessing the first segmented mask pattern comprises:
accessing the first mask pattern comprising a plurality of features; and
converting the first mask pattern into the first segmented mask pattern by segmenting a feature of the plurality of features into a plurality of segments, each segment being a line.

12.-16. (canceled)

17. A non-transitory computer-readable medium having instructions recorded therein, the instructions, when executed by one or more processors, configured to cause the one or more processors to at least:
access a first segmented mask pattern comprising a plurality of segmented features of a first mask pattern;
generate a smoothed representation of the first segmented mask pattern by application of a first smoothing function;
adjust the first segmented mask pattern by a set of changes to one or more of the plurality of segmented features;
generate, using the first smoothing function, a smoothed representation of the adjusted segmented mask pattern;
evaluate the smoothed representation by performance of a computer simulation of a patterning process using the smoothed representation of the adjusted segmented mask pattern;
obtain, based on the adjusted segmented mask pattern, a resultant segmented mask pattern; and
generate, based on a second smoothing function and the resultant segmented mask pattern, a mask pattern having smoothed features for a lithographic process.

18. The medium of claim 17, wherein the instructions configured to cause the one or more processors to obtain the resultant segmented mask pattern are configured to cause the one or more processors to do so in an iterative manner, each iteration comprising simulation of the patterning process that includes one or more process models configured to apply the smoothing function to the segmented mask pattern.

19. The medium of claim 18, wherein the instructions are further configured to cause the one or more processors to, for each iteration:
(a) adjust the first segmented mask pattern with a first change of the set of changes of the more or more of the plurality of segmented features;
(b) generate, using the first smoothing function, the smoothed representation of the adjusted segmented mask pattern;
(c) simulate the patterning process using the smoothed representation of the adjusted segmented mask pattern;
(d) globally evaluate the simulation results based on the adjusted segmented pattern;
(e) determine whether the simulation results satisfy a termination condition; and
(f) responsive to the termination condition not being satisfied, adjust based on the evaluation, the first segmented mask pattern with a second change of the set of changes of the one or more of the plurality of segmented features, and repeat (b)-(f).

20. The medium of claim 17, wherein the instructions configured to cause the one or more processors to evaluate the smoothed representation are further configured cause the one or more processors to:
calculate a Jacobian matrix, wherein the Jacobian matrix comprises a set of derivatives of a function of the smoothed representation with respect to the plurality of segments of the first segmented mask pattern; and
evaluate the cost function using the Jacobian matrix.

21. The medium of claim 17, wherein the instructions configured to cause the one or more processors to evaluate the smoothed representation are further configured cause the one or more processors to evaluate a cost function comprising a lithographic metric correlated to the set of changes to one or more of the plurality of segmented features for a plurality of lithographic process conditions, wherein the cost function comprises a function of the smoothed representation.

22. The medium of claim 21, wherein the instructions are further configured to cause the one or more processors to execute a multi-variable solver implementing the cost function and a Jacobian matrix to generate a free form mask pattern.

23. The medium of claim 21, wherein the cost function is a function of at least one selected from:
relative alignment of at least a pair of the plurality of segmented features,
magnitudes of the changes to the plurality of segmented features, or
characteristics of a resist image or an aerial image.

24. The medium of claim 21, wherein the cost function is a function of a probability of a function of the features and a process window defined by the plurality of lithographic process conditions having a value outside a permitted range.

25. The medium of claim 21, wherein the cost function is a function of one or more selected from: edge placement error, critical dimension uniformity, dose variation, focus variation, process condition variation, mask error (MEEF), mask complexity, resist contour distance, worst defect size, best focus shift, or mask rule constraint.

26. The medium of claim 17, wherein the first mask pattern comprises a plurality of curved features, and wherein the plurality of segmented features of the first segmented mask pattern correspond to the plurality of curved features.

27. The medium of claim 17, wherein the instructions configured to cause the one or more processors to access the first segmented mask pattern are further configured cause the one or more processors to:
access the first mask pattern comprising a plurality of features; and
convert the first mask pattern into the first segmented mask pattern by segmenting a feature of the plurality of features into a plurality of segments, each segment being a line.

28. The medium of claim 27, wherein the instructions configured to cause the one or more processors to convert the first mask pattern into the first segmented mask pattern are further configured cause the one or more processors to approximate the feature of the first mask pattern into the plurality of segments, each segment being oriented at a desired angle with respect to an adjacent segment.

29. The medium of claim 27, wherein the instructions configured to cause the one or more processors to convert the first mask pattern into the first segmented mask pattern are further configured cause the one or more processors to dissect the feature of the first mask pattern into the plurality of segments to generate staircased features, wherein each segment is oriented at 90° angle with respect to an adjacent segment.

30. The medium of claim 17, wherein the first and the second smoothing functions are Gaussian functions.

31. The medium of claim 17, wherein the first smoothing function and the second smoothing function are the same or different.
